(19) United States
(12) Patent Application Publication
(10) Pub. No.: US 2023/0197902 A1
(43) Pub. Date: Jun. 22, 2023

(54) DISPLAY DEVICE

(71) Applicant: Samsung Display Co., LTD., Yongin-si (KR)

(72) Inventors: Jin Yool KIM, Asan-si (KR); Seul Ki KIM, Gwangmyeong-si (KR); Min Seong YI, Seoul (KR); Seon Beom JI, Seoul (KR); Tae Ha JIN, Yongin-si (KR); Dong Hwan KIM, Hwaseong-si (KR)

(73) Assignee: Samsung Display Co., LTD., Yongin-si (KR)

(21) Appl. No.: 17/894,647

(22) Filed: Aug. 24, 2022

(30) Foreign Application Priority Data
Dec. 16, 2021 (KR) 10-2021-0180405

(51) Int. Cl. H01L 33/38; H01L 33/62; H01L 25/075

(52) U.S. Cl. CPC H01L 33/382; H01L 33/62; H01L 25/0753

(57) ABSTRACT

A display device includes a first electrode and a second electrode which are disposed on a substrate and spaced apart from each other, a first insulating layer disposed on the first electrode and the second electrode, a light emitting element disposed on the first insulating layer, and having ends aligned on the first electrode and the second electrode, a first connection electrode disposed on the first electrode and electrically contacting an end of the light emitting element, a second connection electrode disposed on the second electrode and electrically contacting another end of the light emitting element, and a second insulating layer disposed on the first connection electrode and including a repair hole that exposes a portion of the first connection electrode.

### CROSS-REFERENCE TO RELATED APPLICATION(S)

This application claims priority to and the benefit of Korean Patent Application No. 10-2021-0180405 under 35 U.S.C. § 119, filed on Dec. 16, 2021, in the Korean Intellectual Property Office (KIPO), the entire contents of which are incorporated herein by reference.

### BACKGROUND

### 1. Technical Field

The disclosure relates to a display device.

### 2. Description of the Related Art

With the advancement of multimedia, importance of a display device has been enhanced. In this trend, various types of display devices such as an organic light emitting display (OLED) device and a liquid crystal display (LCD) device have been used.

The display device is a device for displaying an image, and includes a display panel such as an organic light emitting display panel or a liquid crystal display panel. The display device may include a light emitting diode as a light emitting display panel, and for example, the light emitting diode (LED) may include an organic light emitting diode that uses an organic material as a light emitting material and an inorganic light emitting diode that uses an inorganic material as a light emitting material.

### SUMMARY

An object of the disclosure is to provide a display device that may repair a defect caused by a short of a light emitting element.

The objects of the disclosure are not limited to those mentioned above and additional objects of the disclosure, which are not mentioned herein, will be clearly understood by those skilled in the art from the following description of the disclosure.

According to an embodiment of the disclosure, a display device may comprise a first electrode and a second electrode which are disposed on a substrate and spaced apart from each other, a first insulating layer disposed on the first electrode and the second electrode, a light emitting element disposed on the first insulating layer and having ends aligned on the first electrode and the second electrode, a first connection electrode disposed on the first electrode and electrically contacting an end of the light emitting element, a second connection electrode disposed on the second electrode and electrically contacting another end of the light emitting element, and a second insulating layer disposed on the first connection electrode and including a repair hole that exposes a portion of the first connection electrode.

In an embodiment, at least a portion of the repair hole may overlap the first connection electrode in a plan view.

In an embodiment, the display device may further comprise a bank layer disposed on the first insulating layer and partitioning a light emission area, wherein the light emitting element is disposed in the light emission area, and a sub-area is spaced apart from the light emission area in a plan view.

In an embodiment, the repair hole may overlap the light emission area and the bank layer in a plan view.

In an embodiment, the repair hole may not overlap the light emission area and may overlap the bank layer in a plan view.

In an embodiment, the display device may further comprise a conductive pad disposed on the second insulating layer and electrically contacting the first connection electrode through the repair hole.

In an embodiment, the conductive pad may overlap the repair hole in a plan view, and may completely cover the repair hole.

In an embodiment, the display device may further comprise at least one transistor disposed on the substrate, wherein a power voltage may be applied to the first connection electrode through the at least one transistor.

In an embodiment, the display device may further comprise a third insulating layer covering a portion of the light emitting element, and a fourth insulating layer covering the third insulating layer and the second connection electrode, wherein the second insulating layer may cover the third insulating layer and the fourth insulating layer.

In an embodiment, the first connection electrode may be disposed between the third insulating layer and the fourth insulating layer, and the second connection electrode is disposed between the second insulating layer and the third insulating layer.

According to an embodiment of the disclosure, a display device may comprise a first electrode and a second electrode which are disposed on a substrate, extended in a first direction and spaced apart from each other in a second direction, a third electrode spaced apart from the first electrode and the second electrode in the second direction between the first electrode and the second electrode, a fourth electrode spaced apart from the first electrode in the first direction, light emitting elements including a first light emitting element having ends disposed on the first electrode and the third electrode, and a second light emitting element having ends disposed on the second electrode and the fourth electrode, a first connection electrode disposed on the first electrode and electrically contacting the first light emitting element, a second connection electrode disposed on the second electrode and electrically contacting the second light emitting element, a third connection electrode disposed on the third electrode and electrically contacting the first light emitting element, a fourth connection electrode disposed on the fourth electrode and electrically contacting the second light emitting element, and a first insulating layer disposed on the first connection electrode and including a first repair hole that exposes a portion of the first connection electrode.

In an embodiment, at least a portion of the first repair hole may overlap the first connection electrode in a plan view.

In an embodiment, the display device may further comprise a conductive pad disposed on the first insulating layer and electrically contacting the first connection electrode through the first repair hole.

In an embodiment, the display device may further comprise a second insulating layer disposed on the first insulating layer and including a second repair hole that exposes the conductive pad, wherein the first repair hole and the second repair hole may overlap each other in a plan view.

In an embodiment, the first connection electrode and the second connection electrode, and the third connection electrode and the fourth connection electrode may be disposed on different layers, and the conductive pad, the third connection electrode, and the fourth connection electrode may include a same material.

In an embodiment, the display device may further comprise a second insulating layer disposed between the first insulating layer and the conductive pad and including a second repair hole that exposes the first repair hole, wherein the conductive pad may electrically contact the first connection electrode through the first repair hole and the second repair hole.

In an embodiment, the first connection electrode, the second connection electrode, the third connection electrode and the fourth connection electrode may be disposed on a same layer, and the first insulating layer may cover the first connection electrode, the second connection electrode, the third connection electrode, and the fourth connection electrode.

In an embodiment, the display device may further comprise at least one transistor disposed on the substrate, wherein a power voltage may be applied to the first connection electrode through at least one transistor.

In an embodiment, the display device may further comprise a bank layer disposed on the substrate and partitioning a light emission area, wherein the light emitting element may be disposed in the light emission area, a sub-area may be spaced apart from the light emission area, and the first repair hole may overlap the bank layer in a plan view.

In an embodiment, the first repair hole may not overlap the light emission area in a plan view.

In the display device according to embodiments of the disclosure, a repair process using a metal tip or a conductive brush may be readily performed by exposing a connection electrode that electrically contact a light emitting element.

Also, a non-light emitting defect caused by a short of the light emitting element may be repaired, whereby problems related to dark spots, luminance deterioration and non-uniform image quality of the display device may be solved.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment of the disclosure;

FIG. 2 is a schematic layout view illustrating lines of a display device according to an embodiment of the disclosure;

FIG. 3 is a schematic diagram of an equivalent circuit illustrating a subpixel according to an embodiment of the disclosure;

FIG. 4 is a schematic plan view illustrating a pixel of a display device according to an embodiment of the disclosure;

FIG. 5 is a schematic cross-sectional view taken along line N1-N1′ of FIG. 4;

FIG. 6 is a schematic cross-sectional view taken along line N2-N2′ of FIG. 4;

FIG. 7 is a schematic view illustrating a light emitting element according to an embodiment of the disclosure;

FIG. 8 is a schematic view illustrating a short defect of a light emitting element;

FIG. 9 is a schematic view illustrating that an overcurrent is applied to a light emitting element;

FIG. 10 is a schematic view illustrating a short defect of a light emitting element is repaired;

FIG. 11 is a schematic cross-sectional view illustrating a subpixel of a display device according to another embodiment of the disclosure;

FIG. 12 is a schematic plan view illustrating a subpixel of a display device according to another embodiment of the disclosure;

FIG. 13 is a schematic cross-sectional view taken along line N3-N3′ of FIG. 12;

FIG. 14 is a schematic cross-sectional view taken along the line N4-N4′ of FIG. 12;

FIG. 15 is a schematic cross-sectional view taken along the line N5-N5′ of FIG. 12;

FIG. 16 is a schematic cross-sectional view illustrating a subpixel of a display device according to still another embodiment of the disclosure;

FIG. 17 is a schematic plan view illustrating a subpixel of a display device according to further still another embodiment of the disclosure;

FIG. 18 is a schematic cross-sectional view illustrating an example taken along line N6-N6′ of FIG. 17;

FIG. 19 is a schematic cross-sectional view illustrating another example taken along the line N6-N6′ of FIG. 17;

FIG. 20 is a schematic cross-sectional view illustrating an example of a subpixel of a display device according to further still another embodiment of the disclosure; and

FIG. 21 is a schematic cross-sectional view illustrating another example of a subpixel of a display device according to further still another embodiment of the disclosure.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will convey the scope of the disclosure to those skilled in the art.

It will also be understood that in case that a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The term “overlap” or “at least partially overlap” as used herein may mean that at least part of a first object faces at least part of a second object in a given direction or given view.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Each of the features of the various embodiments of the disclosure may be combined or combined with each other, in part or in whole, and technically various interlocking and driving are possible. Each embodiment may be implemented independently of each other or may be implemented together in an association.

Hereinafter, detailed embodiments of the disclosure will be described with reference to the accompanying drawings.

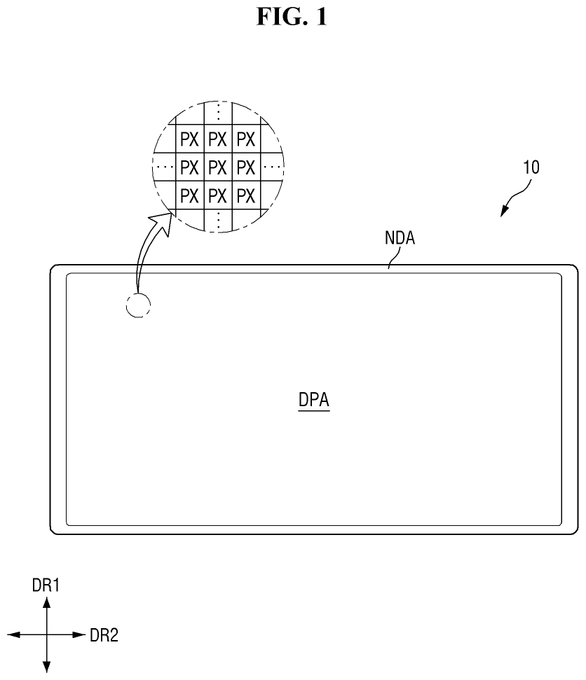

FIG. 1 is a schematic plan view illustrating a display device according to an embodiment of the disclosure.

Referring to FIG. 1, a display device 10 displays a moving image or a still image. The display device 10 may refer to all electronic devices that provide a display screen. For example, a television, a laptop computer, a monitor, an advertising board, Internet of Things, a mobile phone, a smart phone, a tablet personal computer (PC), an electronic watch, a smart watch, a watch phone, a head mounted display, a mobile communication terminal, an electronic diary, an electronic book, a portable multimedia player (PMP), a navigator, a game machine, a digital camera, a camcorder and the like may be included in the display device 10.

The display device 10 includes a display panel for providing a display screen. Examples of the display panel may include an inorganic light emitting diode display panel, an organic light emitting display panel, a quantum dot light emitting display panel, a plasma display panel and a field emission display panel. Hereinafter, an inorganic light emitting diode display panel may be applied as an example of a display panel, but is not limited thereto. Another display panel may be used in case that the same technical spirits are applicable thereto.

Various modifications may be made in a shape of the display device 10. For example, the display device 10 may have a rectangular shape that is long in a horizontal direction, a rectangular shape that is long in a vertical direction, a square shape, a rectangular shape with rounded corners (vertexes), other polygonal shape, a circular shape, etc. A shape of a display area DPA of the display device 10 may be similar to an overall shape of the display device 10. The display device 10 having a rectangular shape that is long in a second direction DR2 may be illustrated in FIG. 1.

The display device 10 may include a display area DPA and a non-display area NDA. The display area DPA is an area in which an image may be displayed, and the non-display area NDA is an area in which an image is not displayed. The display area DPA may be referred to as an active area, and the non-display area NDA may be referred to as an inactive area. The display area DPA may generally occupy the center of the display device 10.

The display area DPA may include pixels PX. Pixels PX may be arranged in a matrix direction. A shape of each pixel PX may be a rectangular or square shape on a plane, but is not limited thereto. The shape of each pixel PX may be a rhombus shape in which each side is inclined with respect to one direction. The respective pixels PX may be arranged in a stripe type or a PENTILE™ type. Each of the pixels PX may include one or more light emitting elements for emitting light of a specific wavelength band to display a specific color.

The non-display area NDA may be disposed in the vicinity of the display area DPA. The non-display area NDA may fully or partially surround the display area DPA. The display area DPA may be rectangular in shape, and the non-display area NDA may be disposed to be adjacent to four sides of the display area DPA. The non-display area NDA may constitute a bezel of the display device 10. Lines or circuit drivers included in the display device 10 may be disposed in the non-display areas NDA, or external devices may be packaged therein.

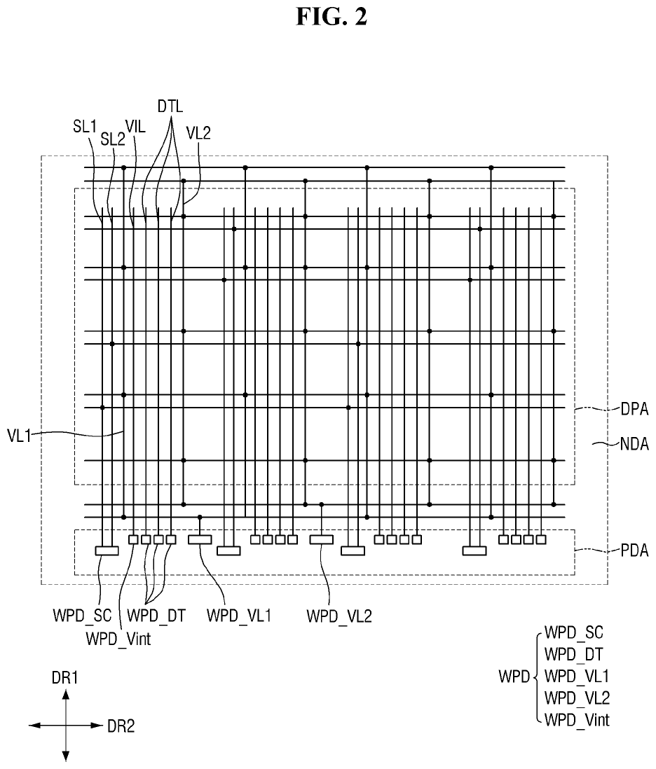

FIG. 2 is a schematic layout view illustrating lines of a display device according to an embodiment of the disclosure.

Referring to FIG. 2, the display device 10 may include lines. The lines may include scan lines SL, data lines DTL, an initialization voltage line VIL and voltage lines VL: VL1 and VL2. Also, although not shown in the drawing, the display device 10 may further include other lines.

The scan line SL may be disposed to be extended in a first direction DR1. The scan line SL may be electrically connected to a scan wiring pad WPD_SC electrically connected to a scan driver (not shown). The scan line SL may be disposed to be extended from a pad area PDA, which is disposed in the non-display area NDA, to the display area DPA.

The meaning of ‘connection’ herein may mean that any one member is electrically connected to another member through other member as well as a mutual physical contact. Also, it may be understood that one portion and another portion are electrically connected with each other as an integrated member. Further, the connection between any one member and another member may be interpreted as including electrical connection through other member in addition to direct connection.

The data lines DTL may be disposed to be extended in the first direction DR1. The data lines DTL may be disposed to be adjacent to one another while forming a pair of three. Each data line DTL may be disposed to be extended from the pad area PDA disposed in a non-display area NDA to the display area DPA.

The initialization voltage line VIL may be disposed to be also extended in the first direction DR1. The initialization voltage line VIL may be disposed between the data lines DTL and the scan line SL. The reset voltage line VIL may be disposed to be extended from the pad area PDA disposed in the non-display area NDA to the display area DPA.

The first voltage line VL1 and the second voltage line VL2 may include a portion extended in the first direction DR1 and a portion extended in the second direction DR2. The portion of the first voltage line VL1 and the second voltage line VL2, which is extended in the first direction DR1, may be disposed to cross the display area DPA, and some lines of the portion extended in the second direction DR2 may be disposed in the display area DPA and the other lines thereof may be disposed in the non-display area NDA positioned on both sides of the first direction DR1 of the display area DPA. The first voltage line VL1 and the second voltage line VL2 may have a mesh structure on an entire surface of the display area DPA.

The scan line SL, the data line DTL, the initialization voltage line VIL, the first voltage line VL1 and the second voltage line VL2 may be electrically connected to at least one wiring pad WPD. Each wiring pad WPD may be disposed in the non-display area NDA. Each wiring pad WPD may be disposed in the pad area PDA positioned at a lower side that is the other side of the display area DPA in the first direction DR1, but various modifications may be made in the position of the pad area PDA depending on a size and specification of the display device 10. The scan line SL may be electrically connected to a scan wiring pad WPD_SC disposed in the pad area PDA, and the data lines DTL may be electrically connected to their respective data line pads WPD_DT different from one another. The initialization voltage line VIL may be electrically connected to an initialization wiring pad WPD_Vint, the first voltage line VL1 may be electrically connected to a first voltage wiring pad WPD_VL1, and the second voltage line VL2 may be electrically connected to a second voltage wiring pad WPD_VL2. An external device may be packaged on the wiring pad WPD. The external device may be packaged on the wiring pad WPD through an anisotropic conductive film, an ultrasonic bonding or the like. In the drawing, each wiring pad WPD may be disposed in the pad area PDA disposed below the display area DPA, but is not limited thereto. Some of the wiring pads WPD may be disposed on an upper side or any one of left and right sides of the display area DPA.

Each pixel PX or subpixel SPXn (n is an integer of 1 to 3) of the display device 10 may include a pixel driving circuit. The above-described lines may apply a driving signal to each pixel driving circuit while passing through each pixel PX and the periphery of each pixel. The pixel driving circuit may include a transistor and a capacitor. Various modifications may be made in the number of transistors and capacitors of each pixel driving circuit. According to an embodiment, each subpixel SPXn of the display device 10 may have a 3T1C structure that includes three transistors and one capacitor. Hereinafter, the pixel driving circuit will be described based on the 3T1C structure, but is not limited thereto. Various modified pixel structures such as a 2TIC structure, a 7TIC structure and a 6TIC structure may be applied to the pixel driving circuit.

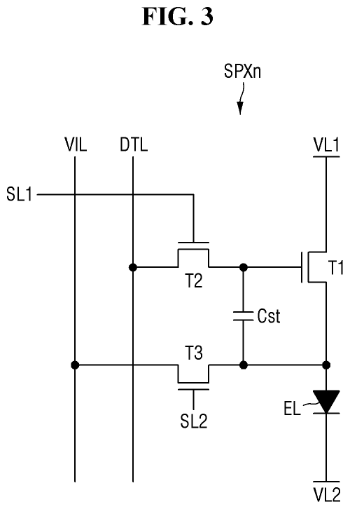

FIG. 3 is a schematic diagram of an equivalent circuit illustrating a subpixel according to an embodiment of the disclosure.

Referring to FIG. 3, each subpixel SPXn of the display device 10 according to an embodiment may include a light emitting diode (or light emitting element) EL, transistors T1, T2 and T3, and a storage capacitor Cst.

The light emitting diode EL may emit light in accordance with a current supplied through the first transistor T1. The light emitting diode EL may include a first electrode, a second electrode, and at least one light emitting element disposed between the first electrode and the second electrode. The light emitting element may emit light of a specific wavelength band by an electrical signal transferred from the first electrode and the second electrode.

One end of the light emitting diode EL may be electrically connected to a source electrode of the first transistor T1, and the other end (or another end) thereof may be electrically connected to the second voltage line VL2 supplied with a low potential voltage (hereinafter, second power voltage) lower than a high potential voltage (hereinafter, first power voltage) of the first voltage line VL1. Further, the other end of the light emitting diode EL may be electrically connected to a source electrode of the second transistor T2.

The first transistor T1 adjusts a current flowing from the first voltage line VL1, to which the first power voltage may be supplied, to the light emitting diode EL in accordance with a voltage difference between a gate electrode and the source electrode. For example, the first transistor T1 may be a driving transistor for driving the light emitting diode EL. The gate electrode of the first transistor T1 may be electrically connected to the source electrode of the second transistor T2, the source electrode thereof may be electrically connected to the first electrode of the light emitting diode EL, and a drain electrode thereof may be electrically connected to the first voltage line VL1 to which the first power voltage is applied.

The second transistor T2 may be turned on by the scan signal of the first scan line SL1 to connect the data line DTL to the gate electrode of the first transistor T1. A gate electrode of the second transistor T2 may be electrically connected to the first scan line SL1, the source electrode thereof may be electrically connected to the gate electrode of the first transistor T1, and a drain electrode thereof may be electrically connected to the data line DTL.

The third transistor T3 may be turned on by the scan signal of the second scan line SL2 to connect the initialization voltage line VIL to one end of the light emitting diode EL. A gate electrode of the third transistor T3 may be electrically connected to the second scan line SL2, a drain electrode thereof may be electrically connected to the initialization voltage line VIL, and a source electrode thereof may be electrically connected to one end of the light emitting diode EL or the source electrode of the first transistor T1. The second transistor T2 and the third transistor T3 may be simultaneously turned on by the same scan signal.

In an embodiment, the source and drain electrodes of each of the transistors T1, T2 and T3 may not be limited to those described above, and may be opposite cases of those described above. Each of the transistors T1, T2 and T3 may be formed of a thin film transistor. In FIG. 3, each of the transistors T1, T2 and T3 may be formed of N-type metal oxide semiconductor field effect transistor (MOSFET), but is not limited thereto. For example, each of the transistors T1, T2 and T3 may be formed of P-type MOSFET, or a portion of the transistors T1, T2 and T3 may be N-type MOSFET and the other portion may be formed of P-type MOSFET.

The storage capacitor Cst may be formed between the gate electrode and the source electrode of the first transistor T1. The storage capacitor Cst may store a differential voltage of a gate voltage and a source voltage of the first transistor T1.

Hereinafter, a structure of a pixel PX of the display device 10 according to an embodiment will be described in detail with reference to another drawing.

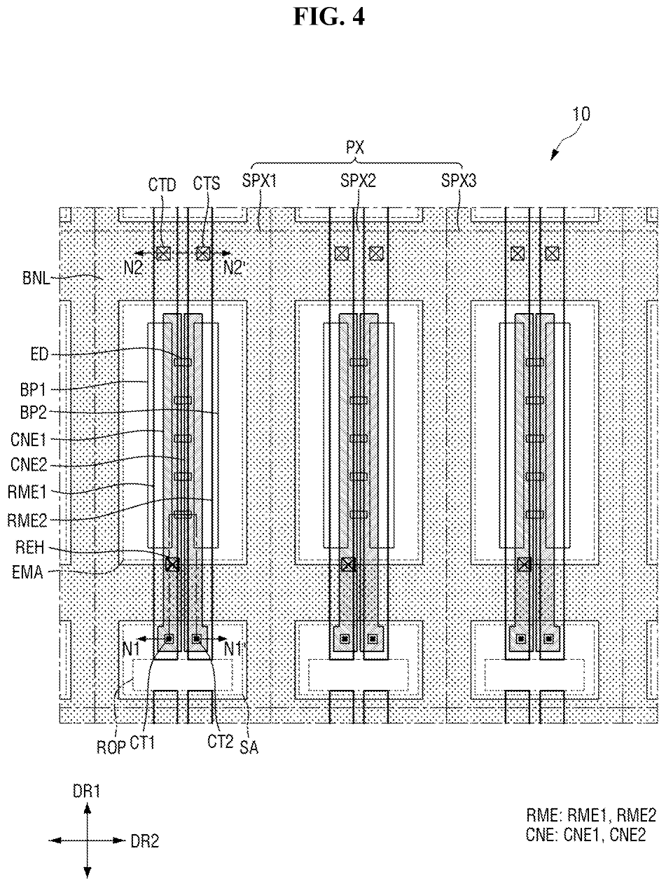

FIG. 4 is a schematic plan view illustrating a pixel of a display device according to an embodiment of the disclosure.

Referring to FIG. 4, each of pixels PX of the display device 10 may include subpixels SPXn (n is an integer of 1 to 3). For example, a pixel PX may include a first subpixel SPX1, a second subpixel SPX2 and a third subpixel SPX3. The first subpixel SPX1 may emit light of a first color, the second subpixel SPX2 may emit light of a second color, and the third subpixel SPX3 may emit light of a third color. For example, the first color may be blue, the second color may be green, and the third color may be red. However, without limitation to this example, each of the subpixels SPXn may emit light of the same color. Although a pixel PX is illustrated as including three subpixels SPXn, the pixel PX may include more than three subpixels SPXn.

Each of the subpixels SPXn of the display device 10 may include a light emission area EMA and a non-light emission area. The light emission area EMA may be an area in which the light emitting element ED is disposed so that light of a specific wavelength band is emitted. The non-light emission area may be an area in which the light emitting element ED is not disposed and light emitted from the light emitting element ED does not reach so that the light is not emitted.

The light emission area EMA may include an area in which the light emitting element ED is disposed, and thus may include an area in which light emitted from the light emitting element ED is emitted to an area adjacent to the light emitting element ED. Without limitation to this case, the light emission area EMA may also include an area in which light emitted from the light emitting element ED is reflected or refracted by another member. The light emitting elements ED may be disposed in each subpixel SPXn, and the area in which the light emitting elements ED are disposed and its adjacent area may form the light emission area.

The light emission areas EMA of each subpixel SPXn may have a uniform size, but are not limited thereto. In some embodiments, the light emission areas EMA of each subpixel SPXn may have their respective sizes different from each other depending on the color or wavelength band of light emitted from the light emitting element ED disposed in the corresponding subpixel SPXn.

Each subpixel SPXn may further include a sub-area SA disposed in the non-light emission area. The sub-area SA may be disposed on one side of the light emission area EMA in the first direction DR1 and thus disposed between the light emission areas EMA of the subpixels SPXn, which are adjacent to each other in the first direction DR1. For example, the light emission areas EMA and the sub-areas SA may be repeatedly arranged in the second direction DR2, and may be alternately arranged in the first direction DR1, but are not limited thereto. However, the light emission areas EMA and the sub-areas SA in the pixels PX may have an arrangement different from that of FIG. 4.

A bank layer BNL may be disposed between the sub-areas SA and the light emission areas EMA, and an interval between the sub-areas SA and the light emission areas EMA may vary depending on a width of the bank layer BNL. Since the light emitting element ED may not be disposed in the sub-area SA, light is not emitted from the sub-area SA but a portion of an electrode RME disposed in each subpixel SPXn may be disposed in the sub-area SA. The electrodes RME disposed in different subpixels SPXn may be disposed to be spaced apart from each other by a partition portion ROP of the sub-area SA.

The bank layer BNL may include portions extended in the first direction DR1 and the second direction DR2 on a plane, and thus may be disposed on the entire surface of the display area DPA in a lattice pattern. The bank layer BNL may be disposed over a boundary of the respective subpixels SPXn to distinguish the subpixels SPXn adjacent to each other. The bank layer BNL may be disposed to surround the light emission area EMA disposed for each subpixel SPXn, thereby distinguishing the light emission areas EMA.

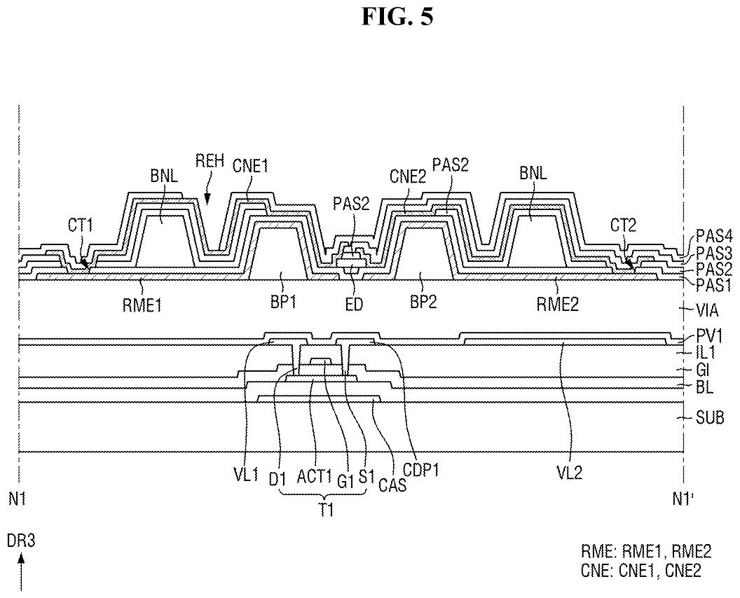

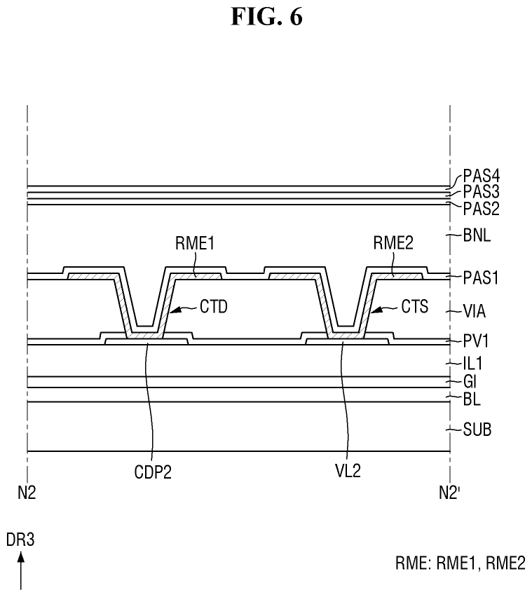

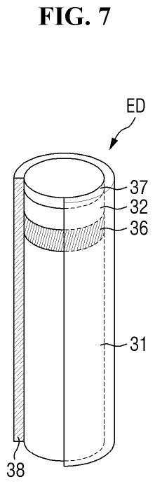

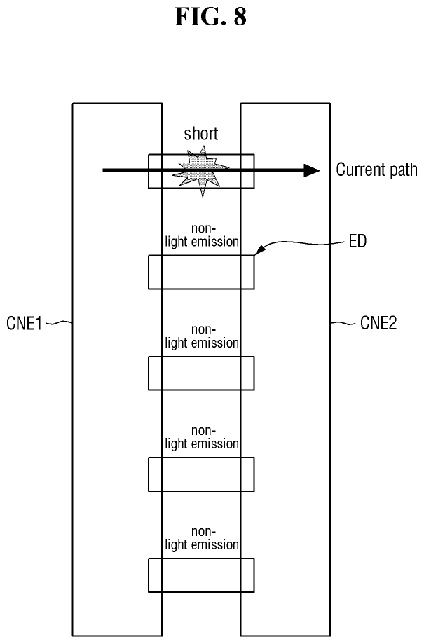

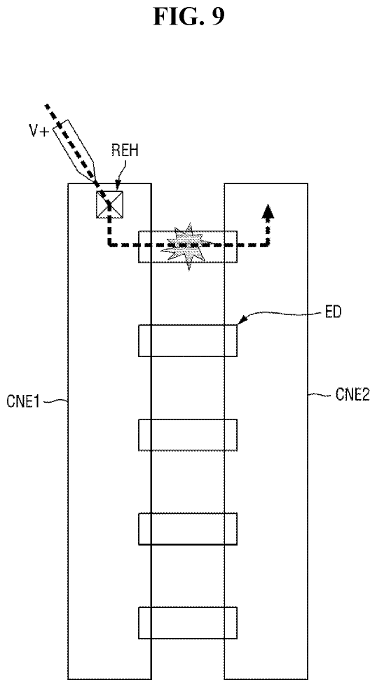

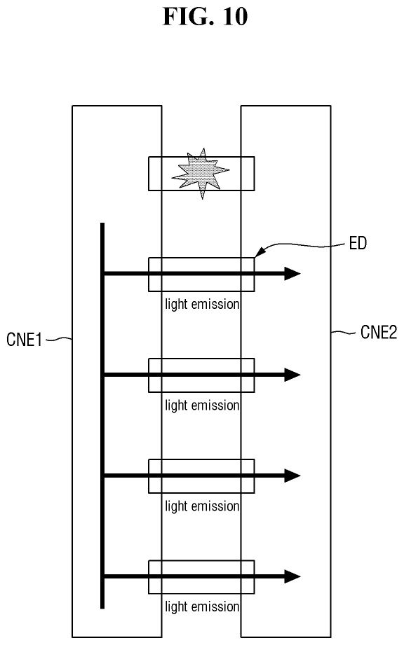

FIG. 5 is a schematic cross-sectional view taken along line N1-N1′ of FIG. 4. FIG. 6 is a schematic cross-sectional view taken along line N2-N2′ of FIG. 4. FIG. 7 is a schematic view illustrating a light emitting element according to an embodiment of the disclosure. FIG. 8 is a schematic view illustrating a short defect of a light emitting element. FIG. 9 is a schematic view illustrating that an overcurrent is applied to a light emitting element. FIG. 10 is a schematic view illustrating a short defect of a light emitting element is repaired.

Referring to FIGS. 4 to 6, the display device 10 may include a first substrate SUB, a semiconductor layer disposed on the first substrate SUB, conductive layers, and insulating layers. The semiconductor layer, the conductive layer and the insulating layers may constitute a circuit layer and a display element layer of the display device 10, respectively.

In detail, the first substrate SUB may be an insulating substrate. The first substrate SUB may be made of an insulating material such as glass, quartz or polymer resin. The first substrate SUB may be a rigid substrate, but may be a flexible substrate capable of being subjected to bending, folding, rolling or the like. The first substrate SUB may include a display area DPA, a non-display area NDA surrounding the display area DPA, and a pad area PDA corresponding to a portion of the non-display area NDA.

A first conductive layer may be disposed on the first substrate SUB. The first conductive layer may include a lower metal layer CAS that is disposed to overlap an active layer ACT1 of the first transistor T1. The lower metal layer CAS may include a light shielding material to prevent light from entering the active layer ACT1 of the first transistor. However, the lower metal layer CAS may be omitted.

A buffer layer BL may be disposed on the lower metal layer CAS and the first substrate SUB. The buffer layer BL may be formed on the first substrate SUB to protect the transistors of the pixel PX from moisture permeated through the first substrate SUB vulnerable to moisture permeation, and may perform a surface planarization function.

The semiconductor layer may be disposed on the buffer layer BL. The semiconductor layer may include the active layer ACT1 of the first transistor T1. The active layer ACT1 may be disposed to partially overlap a gate electrode G1 of a second conductive layer, which will be described below.

The semiconductor layer may include at least one of polycrystalline silicon, monocrystalline silicon, an oxide semiconductor, and the like, or a combination thereof. In other embodiment, the semiconductor layer may include polycrystalline silicon. The oxide semiconductor may be an oxide semiconductor containing indium (In). For example, the oxide semiconductor may be at least one of Indium Tin Oxide (ITO), Indium Zinc Oxide (IZO), Indium Gallium Oxide (IGO), Indium Zinc Tin Oxide (IZTO), Indium Gallium Tin Oxide (IGTO), Indium Gallium Zinc Oxide (IGZO), and Indium Gallium Zinc Tin Oxide (IGZTO), or a combination thereof.

Although one first transistor T1 is illustrated as being disposed in the subpixels SPXn of the display device 10, it is not limited thereto. The display device 10 may include a larger number of transistors.

A first gate insulating layer GI may be disposed on the semiconductor layer and the buffer layer BL. The first gate insulating layer GI may serve as a gate insulating layer of the first transistor T1.

The second conductive layer may be disposed on the first gate insulating layer GI. The second conductive layer may include a gate electrode G1 of the first transistor T1. The gate electrode G1 may be disposed to overlap a channel area of the active layer ACT1 in a third direction DR3 that is a thickness direction.

A first interlayer insulating layer IL1 may be disposed on the second conductive layer. The first interlayer insulating layer IL1 may serve as an insulating layer between the second conductive layer and other layers disposed on the second conductive layer, and may protect the second conductive layer.

A third conductive layer may be disposed on the first interlayer insulating layer ILL The third conductive layer may include a first voltage line VL1 and a second voltage line VL2, which are disposed in the display area DPA, conductive patterns CDP1 and CDP2, and a pad electrode base layer PEL of a pad electrode PE disposed in the pad area PDA.

A high potential voltage (or first power voltage) transferred to a first electrode RME1 may be applied to the first voltage line VL1, and a low potential voltage (or second power voltage) transferred to a second electrode RME2 may be applied to the second voltage line VL2. A portion of the first voltage line VL1 may electrically contact the active layer ACT1 of the first transistor T1 through a contact hole that passes through the first interlayer insulating layer IL1 and the first gate insulating layer GI. The first voltage line VL1 may serve as a first drain electrode D1 of the first transistor T1. The second voltage line VL2 may be connected (e.g., directly connected) to the second electrode RME2 that will be described below.

The first conductive pattern CDP1 may electrically contact the active layer ACT1 of the first transistor T1 through the contact hole that passes through the first interlayer insulating layer IL1 and the first gate insulating layer GI. The first conductive pattern CDP1 may electrically contact the lower metal layer CAS through another contact hole. The first conductive pattern CDP1 may serve as a first source electrode S1 of the first transistor T1.

The second conductive pattern CDP2 may be electrically connected to the first electrode RME1 that will be described below. Also, the second conductive pattern CDP2 may be electrically connected to the first transistor T1 through the first conductive pattern CDP1. Although the first conductive pattern CDP1 and the second conductive pattern CDP2 are illustrated as being spaced apart from each other, in some embodiments, the second conductive pattern CDP2 may be integrated with (or integral with) the first conductive pattern CDP1 to form one pattern. The first transistor T1 may transfer the first power voltage applied from the first voltage line VL1 to the first electrode RME1.

The first conductive pattern CDP1 and the second conductive pattern CDP2 may be shown as being formed on the same layer, but are not limited thereto. In some embodiments, the second conductive pattern CDP2 may be formed of a conductive layer different from the first conductive pattern CDP1, for example, a fourth conductive layer disposed on the third conductive layer with some insulating layers interposed therebetween. The first voltage line VL1 and the second voltage line VL2 may be formed of a fourth conductive layer not the third conductive layer, and the first voltage line VL1 may be electrically connected to the drain electrode D1 of the first transistor T1 through another conductive pattern.

A passivation layer PV1 may be disposed on the third conductive layer. The passivation layer PV1 may serve as an insulating layer between the third conductive layer and other layers disposed on the third conductive layer, and may protect the third conductive layer.

The buffer layer BL, the first gate insulating layer GI, the first interlayer insulating layer IL1 and the passivation layer PV1 may be formed of inorganic layers that are alternately stacked each other. For example, the buffer layer BL, the first gate insulating layer GI, the first interlayer insulating layer IL1 and the passivation layer PV1 may be formed of a double layer in which inorganic layers including at least one of silicon oxide (SiOₓ), silicon nitride (SiNₓ), or silicon oxynitride (SiOₓN_{y}) are stacked each other, or multiple layers in which the inorganic layers are alternately stacked each other, but are not limited thereto. The buffer layer BL, the first gate insulating layer GI, the first interlayer insulating layer IL1 and the passivation layer PV1 may be made of one inorganic layer including the insulating material described above. Also, in some embodiments, the first interlayer insulating layer IL1 may be made of an organic insulating material such as polyimide (PI).

The second conductive layer and the third conductive layer may be formed of a single layer or multiple layers made of one of molybdenum (Mo), aluminum (Al), chromium (Cr), gold (Au), titanium (Ti), nickel (Ni), neodymium (Nd) and copper (Cu), or their alloy, but are not limited thereto.

A via layer VIA may be disposed on the passivation layer PV1. The via layer VIA may include an organic insulating material such as polyimide (PI) to perform a surface planarization function.

Bank patterns BP1 and BP2, electrodes RME; RME1 and RME2 and the bank layer BNL, the light emitting elements ED and connection electrodes CNE: CNE1 and CNE2 are disposed on the via layer VIA as display element layers. Insulating layers PAS1, PAS2, PAS3 and PAS4 may be disposed on the via layer VIA.

The bank patterns BP1 and BP2 may be disposed (e.g., disposed directly) on the via layer VIA in the display area DPA. The bank patterns BP1 and BP2 may have a shape extended in the first direction DR1, and may be spaced apart from each other in the second direction DR2. For example, the bank patterns BP1 and BP2 may include a first bank pattern BP1 and a second bank pattern BP2, which are spaced apart from each other in the light emission area EMA of each subpixel SPXn. The first bank pattern BP1 may be disposed on a left side that is one side in the second direction DR2 based on the center of the light emission area EMA, and the second bank pattern BP2 may be disposed on a right side that is the other side in the second direction DR2 based on the center of the light emission area EMA. The light emitting elements ED may be disposed between the first bank pattern BP1 and the second bank pattern BP2.

A length of the bank patterns BP1 and BP2 extended in the first direction DR1 may be smaller than that of the light emission area EMA surrounded by the bank layer BNL in the first direction DR1. The bank patterns BP1 and BP2 may be disposed in the light emission area EMA of the subpixels SPXn on the entire surface of the display area DPA to form an island-shaped pattern extended in one direction at a narrow width. Two bank patterns BP1 and BP2 are illustrated as being disposed at the same width for each subpixel SPXn, but are not limited thereto. The number and shape of the bank patterns BP1 and BP2 may vary depending on the number or arrangement structure of the electrodes RME.

The bank patterns BP1 and BP2 may have a structure in which at least a portion is protruded based on an upper surface of the via layer VIA. The protruded portion of the bank patterns BP1 and BP2 may have an inclined side, and light emitted from the light emitting element ED may be reflected by the electrodes RME disposed on the bank patterns BP1 and BP2 and emitted toward an upper direction of the via layer VIA, but the disclosure is not limited thereto. An outer surface of the bank patterns BP1 and BP2 may have a semicircular or semi-elliptical shape. The bank patterns BP1 and BP2 may include, but are not limited to, an organic insulating material such as polyimide (PI).

The electrodes RME are disposed in each subpixel SPXn in a shape extended in one direction. The electrodes RME may be extended in the first direction DR1 and disposed in the light emission area EMA of the subpixels SPXn, and may be spaced apart from each other in the second direction DR2. The electrodes RME may be electrically connected to the light emitting element ED. Each of the electrodes RME may be electrically connected to the light emitting element ED through connection electrodes CNE: CNE1 and CNE2, which will be described below, and may transfer an electrical signal applied from a conductive layer therebelow to the light emitting element ED.

The display device 10 may include a first electrode RME1 and a second electrode RME2, which are disposed in each subpixel SPXn. The first electrode RME1 may be disposed on a left side based at the center of the light emission area EMA, and the second electrode RME2 may be spaced apart from the first electrode RME1 in the second direction DR2 and may be disposed on a right side based at the center of the light emission area EMA. The first electrode RME1 may be disposed on the first bank pattern BP1, and the second electrode RME2 may be disposed on the second bank pattern BP2. The first electrode RME1 and the second electrode RME2 may be partially disposed in the corresponding subpixel SPXn and the sub-area SA beyond the bank layer BNL. The first and second electrodes RME1 and RME2 of different subpixels SPXn may be spaced apart from each other based on the partition portion ROP positioned in the sub-area SA of any a subpixel SPXn.

The first electrode RME1 and the second electrode RME2 may be disposed on the inclined side of the bank patterns BP1 and BP2. In an embodiment, a width of the electrodes RME, which is measured in the second direction DR2, may be smaller than that of the bank patterns BP1 and BP2, which is measured in the second direction DR2. The first electrode RME1 and the second electrode RME2 may be disposed to cover at least one side of the bank patterns BP1 and BP2 to reflect the light emitted from the light emitting element ED.

In addition, an interval between the first electrode RME1 and the second electrode RME2, which are spaced apart from each other in the second direction DR2, may be narrower than that between the bank patterns BP1 and BP2. As at least a portion of the first electrode RME1 or the second electrode RME2 may be disposed (e.g., disposed directly) on the via layer VIA, the first electrode RME1 and the second electrode RME2 may be disposed on the same plane.

As described above, the electrodes RME may be disposed on the bank patterns BP1 and BP2 and the light emitted from the light emitting elements ED disposed between the bank patterns BP1 and BP2 may be reflected by the electrode RME disposed on the bank patterns BP1 and BP2 and emitted toward the upper direction. Each of the electrodes RME may include a conductive material having high reflectance, thereby reflecting the light emitted from the light emitting element ED.

The electrodes RME may include a conductive material having high reflectance. For example, the electrodes RME may include a metal such as silver (Ag), copper (Cu), and aluminum (Al), or a combination thereof, or an alloy containing aluminum (Al), nickel (Ni), lanthanum (La), etc., or may have a stacked structure in which a metal layer such as titanium (Ti), molybdenum (Mo), and niobium (Nb), or a combination thereof, and the alloy are stacked each other. In some embodiments, the electrodes RME may be a double layer or multiple layers in which an alloy containing aluminum (Al) and at least one metal layer of titanium (Ti), molybdenum (Mo) or niobium (Nb) are stacked each other.

Without limitation to the above example, each of the electrodes RME may further include a transparent conductive material. For example, each electrode RME may include a material such as ITO, IZO and ITZO. In some embodiments, each of the electrodes RME may have a structure in which one or more layers of a transparent conductive material and a metal layer having high reflectance are stacked each other, or may be formed as a single layer including the transparent conductive material and the metal layer. For example, each electrode RME may have a stacked structure such as ITO/Ag/ITO/, ITO/Ag/IZO or ITO/Ag/ITZO/IZO. The electrodes RME may be electrically connected to the light emitting elements ED, and may reflect some of the light emitted from the light emitting elements ED in an upper direction of the first substrate SUB.

The first electrode RME1 and the second electrode RME2 may be electrically connected to the third conductive layer through a first electrode contact hole CTD and a second electrode contact hole CTS, which are formed in a portion overlapped with the bank layer BNL, respectively. The first electrode RME1 may electrically contact the second electrode pattern CDP2 through the first electrode contact hole CTD that passes through the via layer VIA therebelow. The second electrode RME2 may electrically contact the second voltage line VL2 through the second electrode contact hole CTS that passes through the via layer VIA therebelow. The first electrode RME1 may be electrically connected to the first transistor T1 through the second electrode pattern CDP2 and the first electrode pattern CDP1 to allow a first power voltage to be applied thereto, and the second electrode RME2 may be electrically connected to the second voltage line VL2 to allow a second power voltage to be applied thereto.

The first insulating layer PAS1 may be disposed on the entire surface of the display area DPA, and may be disposed on the via layer VIA and the electrodes RME. The first insulating layer PAS1 may protect the electrodes RME and at the same time mutually insulate the different electrodes RME. In particular, the first insulating layer PAS1 may be disposed to cover the electrodes RME before the bank layer BNL is formed, thereby preventing the electrodes RME from being damaged in the process of forming the bank layer BNL. The first insulating layer PAS1 may prevent the light emitting element ED disposed thereon from being damaged due to contact (e.g., direct contact) with other members.

In an embodiment, the first insulating layer PAS1 may be stepped such that its upper surface is partially recessed between electrodes RME spaced apart from each other in the second direction DR2. The light emitting element ED may be disposed on the upper surface of the first insulating layer PAS1 that is stepped, and a space may be formed between the light emitting element ED and the first insulating layer PAS1.

According to an embodiment of the disclosure, the first insulating layer PAS1 may be disposed to cover the electrodes RME, and may include openings that expose a portion of the upper surface of the electrodes. For example, the first insulating layer PAS1 may include contact portions CT1 and CT2 that expose the respective electrodes RME. The first contact portion CT1 may be disposed on the first electrode RME1 in the sub-area SA, and may expose a portion of an upper surface of the first electrode RME1. The second contact portion CT2 may be disposed on the second electrode RME2 in the sub-area SA, and may expose a portion of the upper surface of the second electrode RME2. For example, the first contact portion CT1 and the second contact portion CT2 may be disposed outside the bank layer BNL based on the light emission area EMA.

The connection electrodes CNE, which will be described below, may electrically contact each electrode RME exposed through the first contact portion CT1 and the second contact portion CT2. The first insulating layer PAS1 may expose the upper surface of the via layer VA in the partition portion ROP in which the electrodes RME of different subpixels SPXn are spaced apart from each other.

The bank layer BNL may be disposed on the first insulating layer PAS1. The bank layer BNL includes a portion extended in the first direction DR1 and the second direction DR2, and may surround each of the subpixels SPXn. The bank layer BNL may distinguish the light emission area EMA from the sub-area SA while surrounding the light emission area EMA and the sub-area SA of each subpixel SPXn, and may distinguish the display area DPA from the non-display area NDA while surrounding the outermost periphery of the display area DPA. The bank layer BNL may be disposed entirely on the display area DPA to form a lattice pattern, and the areas of the display area DPA, in which the bank layer BNL is exposed, may be the light emission area EMA and the sub-area SA.

The bank layer BNL may have a height similarly to the bank patterns BP1 and BP2. In some embodiments, the bank layer BNL may be higher than the bank patterns BP1 and BP2, and its thickness may be equal to or greater than that of the bank patterns BP1 and BP2. The bank layer BNL may prevent ink from overflowing to the subpixels SPXn adjacent thereto in an inkjet printing process of a manufacturing process of the display device 10. The bank layer BNL may include an organic insulating material such as polyimide in the same manner as the bank patterns BP1 and BP2.

The light emitting elements ED may be disposed on the first insulating layer PAS1. The light emitting element ED may have a shape extended in one direction, and may be disposed such that the extended direction is parallel with the first substrate SUB. As described below, the light emitting element ED may include semiconductor layers disposed along the above extended direction, wherein the semiconductor layers may be sequentially disposed along a direction parallel with an upper surface of the first substrate SUB, but is not limited thereto. In case that the light emitting element ED has another structure, the semiconductor layers may be disposed in a direction perpendicular to the first substrate SUB.

The light emitting elements ED may be disposed on the electrodes RME spaced apart from each other in the second direction DR2 between the bank patterns BP1 and BP2. An extended length of the light emitting element ED may be longer than the interval between the electrodes RME spaced apart from each other in the second direction DR2. The light emitting elements ED may be arranged such that at least one end thereof may be disposed on any one of the different electrodes RME or both ends thereof may be disposed on the different electrodes RME. The light emitting elements ED may be disposed such that both ends thereof are placed on the different electrodes RME1 and RME2 or both ends are placed on the electrodes RME1 and RME2 depending on the structure of the electrodes RME1 and RME2. The direction in which each of the electrodes RME may be extended and the direction in which the light emitting element ED is extended may be perpendicular to each other or almost perpendicular to each other. The light emitting elements ED may be spaced apart from each other along the first direction DR1 in which each of the electrodes RME may be extended, and may be aligned to be parallel with each other or to be almost parallel with each other, but are not limited thereto. The light emitting elements ED may be obliquely disposed in a direction in which each of the electrodes RME is extended.

The light emitting elements ED disposed in the respective subpixels SPXn may emit light having different wavelength bands depending on the material of the semiconductor layer, but are not limited thereto. The light emitting elements ED disposed in the respective subpixels SPXn may include semiconductor layers of a same material to emit light of the same color. The light emitting elements ED may electrically contact the connection electrodes CNE: CNE1 and CNE2 and thus electrically connected to the conductive layers below the electrode RME and the via layer VIA, and may emit light of a specific wavelength band as an electrical signal is applied thereto.

The second insulating layer PAS2 may be disposed on the light emitting elements ED, the first insulating layer PAS1 and the bank layer BNL. The second insulating layer PAS2 may include a pattern portion extended in the first direction DR1 between the bank patterns BP1 and BP2 and disposed on the light emitting elements ED. The pattern portion may be disposed to partially surround an outer surface of the light emitting element ED, and may not cover both sides or both ends of the light emitting element ED. The pattern portion may form a linear or island-shaped pattern within each subpixel SPXn on the plan view. The pattern portion of the second insulating layer PAS2 may protect the light emitting elements ED and at the same time fix the light emitting elements ED in the manufacturing process of the display device 10. The second insulating layer PAS2 may be disposed to fill a space between the light emitting element ED and the second insulating layer PAS2 below the light emitting element ED. Further, a portion of the second insulating layer PAS2 may be disposed on the top of the bank layer BNL and in the sub-areas SA. A portion of the second insulating layer PAS2, which is disposed in the sub-area SA, may not be disposed in the first contact portion CT1, the second contact portion CT2 and the partition portion ROP.

The connection electrodes CNE; CNE1 and CNE2 may be disposed on the electrodes RME and the light emitting elements ED, and may electrically contact them, respectively. The connection electrode CNE may electrically contact any one end of the light emitting element ED, and at least one of the electrodes RME through the contact portions CT1 and CT2 that pass through the first insulating layer PAS1 and the second insulating layer PAS2.

The first connection electrode CNE1 may have a shape extended in the first direction DR1, and may be disposed on the first electrode RME1. A portion of the first connection electrode CNE1, which is disposed on the first bank pattern BP1, may overlap the first electrode RME1, and may be extended from the first electrode RME1 in the first direction DR1. The first connection electrode CNE1 may be disposed from the light emission area EMA to the sub-area SA beyond the bank layer BNL. The first connection electrode CNE1 may electrically contact the first electrode RME1 in the sub-area SA through the first contact portion CT1 that exposes a portion of the first electrode RME1. The first connection electrode CNE1 may electrically contact the light emitting elements ED and the first electrode RME1 to transfer the electrical signal applied from the first transistor T1 to the light emitting element ED.

The second connection electrode CNE2 may have a shape extended in the first direction DR1, and may be disposed on the second electrode RME2. A portion of the second connection electrode CNE2, which is disposed on the second bank pattern BP2, may overlap the second electrode RME2, and may be extended from the second electrode RME2 in the first direction DR1. The second connection electrode CNE2 may be disposed from the light emission area EMA to the sub-area SA beyond the bank layer BNL. The second connection electrode CNE2 may electrically contact the second electrode RME2 in the sub-area SA through the second contact portion CT2 that exposes a portion of the second electrode RME2. The second connection electrode CNE2 may electrically contact the light emitting elements ED and the second electrode RME2 to transfer the electrical signal applied from the second voltage line VL2 to the light emitting element ED.

The third insulating layer PAS3 may be disposed on the second connection electrode CNE2 and the second insulating layer PAS2. The third insulating layer PAS3 may be disposed entirely on the second insulating layer PAS2 to cover the second connection electrode CNE2, and the first connection electrode CNE1 may be disposed on the third insulating layer PAS3. The third insulating layer PAS3 may be disposed entirely on the via layer VIA except the area in which the second connection electrode CNE2 is disposed. The third insulating layer PAS3 may insulate the first connection electrode CNE1 from the second connection electrode CNE2 so that the first connection electrode CNE1 does not contact (e.g., does not directly contact) the second connection electrode CNE2.

The third insulating layer PAS3 may be disposed entirely except the portion of the sub-area SA, in which the first contact portion CT1 is disposed, and may cover the second contact portion CT2 and the partition portion ROP. Since the first connection electrode CNE1 is disposed in the first contact portion CT1, the third insulating layer PAS3 may expose the first contact portion CT1. Since the second connection electrode CNE2 is disposed in the second contact portion CT2, the third insulating layer PAS3 may cover the second contact portion CT2 together with the second connection electrode CNE2. Further, the third insulating layer PAS3 may contact (e.g., directly contact) the upper surface of the via layer VIA, which is exposed as the electrodes RME are spaced apart from each other, by covering the partition portion ROP.

The fourth insulating layer PAS4 may be disposed on the third insulating layer PAS3. The fourth insulating layer PAS4 may be disposed entirely on the third insulating layer PAS3 to cover the first connection electrode CNE1. The fourth insulating layer PAS4 may be disposed entirely on the via layer VIA. The fourth insulating layer PAS4 may protect members disposed therebelow from an external environment.

The fourth insulating layer PAS4 may be entirely disposed in the sub-area SA, and may cover the first contact portion CT1, the second contact portion CT2 and the partition portion ROP. Since each connection electrode CNE is disposed in the first contact portion CT1 and the second contact portion CT2, the fourth insulating layer PAS4 may cover the first contact portion CT1 and the second contact portion CT2 together with each connection electrode CNE.

The first insulating layer PAS1, the second insulating layer PAS2, the third insulating layer PAS3 and the fourth insulating layer PAS4 may include an inorganic insulating material or an organic insulating material.

Referring to FIG. 7, the light emitting element ED may be a light emitting diode, and specifically, the light emitting element ED may be an inorganic light emitting diode made of an inorganic material with a size of a nano-meter to a micro-meter. The light emitting element ED may be aligned between two electrodes having polarities in case that an electric field is formed in a specific direction between the two electrodes facing each other.

The light emitting element ED according to an embodiment of the disclosure may have a shape extended in one direction. The light emitting element ED may have a cylindrical shape, a rod shape, a wire shape or a tube shape, but is not limited thereto. The light emitting element ED may have a polygonal pillar shape such as a cube, a cuboid, and a hexagonal pillar, or may have various shapes such as a shape extended in one direction, having an external surface that is partially inclined.

The light emitting element ED may include a semiconductor layer doped with any conductivity type (e.g., p-type or n-type) impurities. The semiconductor layer may emit light of a specific wavelength band as an electrical signal applied from an outer power source is transferred thereto. The light emitting element ED may include a first semiconductor layer 31, a second semiconductor layer 32, a light emitting layer 36, an electrode layer 37 and an insulating layer 38.

The first semiconductor layer 31 may be an n-type semiconductor. The first semiconductor layer 31 may include a semiconductor material having a formula of AlₓGa_{y}In_{1-x-y}N(0≤x≤1,0≤y≤1, 0≤x+y≤1). For example, the first semiconductor layer 31 may be any one or more of AlGaInN, GaN, AlGaN, InGaN, AlN, and InN, or a combination thereof, which are doped with n-type dopants. The n-type dopants doped in the first semiconductor layer 31 may be Si, Ge, Sn, Se, etc., or a combination thereof.

The second semiconductor layer 32 may be disposed on the first semiconductor layer 31 with the light emitting layer 36 interposed therebetween. The second semiconductor layer 32 may be a p-type semiconductor, and may include a semiconductor material having a chemical formula of AlₓGa_{y}In_{1-x-y}N(0≤x≤1,0≤y≤1, 0≤x+y≤1), or a combination thereof. For example, the second semiconductor layer 32 may be any one or more of AlGaInN, GaN, AlGaN, InGaN, AlN and InN, which are doped with p-type dopants. The p-type dopants doped in the second semiconductor layer 32 may be Mg, Zn, Ca, Ba, etc.

The first semiconductor layer 31 and the second semiconductor layer 32 may be shown as being formed of a single layer, but are not limited thereto. The first semiconductor layer 31 and the second semiconductor layer 32 may further include a larger number of layers, such as a clad layer or a tensile strain barrier reducing (TSBR) layer depending on the material of the light emitting layer 36.

The light emitting layer 36 may be disposed between the first semiconductor layer 31 and the second semiconductor layer 32. The light emitting layer 36 may include a single or multiple quantum well structure material. In case that the light emitting layer 36 may include a material of a multiple quantum well structure, quantum layers and well layers may be alternately stacked each other. The light emitting layer 36 may emit light by combination of electron-hole pairs in accordance with electrical signals applied through the first semiconductor layer 31 and the second semiconductor layer 32. The light emitting layer 36 may include a material such as AlGaN and AlGaInN. In case that the light emitting layer 36 may have a stacked structure of quantum layers and well layers, which are alternately stacked in a multiple quantum well structure, the quantum layer may include a material such as AlGaN or AlGaInN, and the well layer may include a material such as GaN or AlInN.

The light emitting layer 36 may have a structure in which a semiconductor material having a big band gap energy and semiconductor materials having a small band gap energy are alternately stacked each other, and may include group-III or group-V semiconductor materials depending on a wavelength band of light that is emitted. The light emitting layer 36 may emit light of a red or green wavelength band, as the case may be, without being limited to light of a blue wavelength band.

The electrode layer 37 may be an ohmic connection electrode, but is not limited thereto. The electrode layer 37 may be a Schottky connection electrode. The light emitting element ED may include at least one electrode layer 37. The light emitting element ED may include one or more electrode layers 37, but is not limited thereto. The electrode layer 37 may be omitted.

The electrode layer 37 may reduce resistance between the light emitting element ED and an electrode or a connection electrode in case that the light emitting element ED is electrically connected with the electrode or the connection electrode in the display device 10. The electrode layer 37 may include a metal having conductivity. For example, the electrode layer 37 may include at least one of Al, Ti, In, Au, Ag, ITO, IZO and ITZO, or a combination thereof.

The insulating layer 38 may be disposed to surround outer surfaces of the semiconductor layers and electrode layers. For example, the insulating layer 38 may be disposed to surround an outer surface of the light emitting layer 36, and may be formed to expose both ends in a length direction of the light emitting element ED. Also, the insulating layer 38 may be formed with a rounded upper surface on a section in an area adjacent to at least one end of the light emitting element ED.

The insulating layer 38 may include materials having insulation property, for example, silicon oxide (SiOₓ), silicon nitride (SiNₓ), silicon oxynitride (SiOₓN_{y}), aluminum nitride (AlNₓ), aluminum oxide (AlₓO_{y}), etc., or a combination thereof. The insulating layer 38 may be illustrated as being formed of a single layer, but is not limited thereto. In some embodiments, the insulating layer 38 may be formed of a multi-layered structure in which multiple layers are stacked each other.

The insulating layer 38 may serve to protect the above members. The insulating layer 38 may prevent an electrical short that may occur in the light emitting layer 36 in case that the light emitting element ED contacts (e.g., directly contacts) the electrode to which the electrical signal is transferred. The insulating layer 38 may prevent light emitting efficiency of the light emitting element ED from being deteriorated.

Also, an outer surface of the insulating layer 38 may be surface-treated. The light emitting element ED may be aligned by being sprayed onto the electrode in a state that it is dispersed in an ink. The surface of the insulating layer 38 may be treated with hydrophobic or hydrophilic property, so that the light emitting element ED may be maintained to be dispersed in the ink without being condensed with another light emitting element ED adjacent thereto.

The light emitting element ED described above may be aligned by being sprayed onto the first substrate SUB in an ink-jet manner. The light emitting element ED may be manufactured by being grown on a sapphire or silicon substrate, but some of the light emitting elements may be manufactured to be defective, thereby causing a non-light emitting defect in the display device 10.

Referring to FIG. 8, each of the light emitting elements ED may emit light as a current is applied between the first connection electrode CNE1 and the second connection electrode CNE2. However, in case that any one of the light emitting elements ED has a short defect, it may act as a current path between the first connection electrode CNE1 and the second connection electrode CNE2. Since the current applied from the first connection electrode CNE1 flows to the second connection electrode CNE2 through the shorted light emitting element ED, a non-light emitting defect in which the light emitting element ED does not emit light may occur. The non-light emitting defect may cause dark spots, luminance deterioration and non-uniform image quality of the display device 10.

The display device 10 according to an embodiment of the disclosure may repair the non-light emitting defect by applying an overcurrent to the shorted light emitting element ED.

Referring back to FIGS. 4 and 5, the fourth insulating layer PAS4 may include a repair hole REH that exposes the first connection electrode CNE1. The repair hole REH may be disposed in each of the subpixels SPXn. The repair hole REH may be disposed over the light emission area EMA and the non-light emission area of each of the subpixels SPXn. For example, a portion of the repair hole REH may overlap the bank layer BNL and another portion thereof may not overlap the bank layer BNL, but the repair hole REH is not limited thereto. However, the repair hole REH may be disposed in the light emission area EMA, and the repair hole REH may not overlap the bank layer BNL. In another embodiment, the repair hole REH may be disposed in the non-light emission area, and the repair hole REH may overlap the bank layer BNL.

In an embodiment, the repair hole REH may overlap the first connection electrode CNE1 in the third direction DR3. The repair hole REH may expose the first connection electrode CNE1 to which the first power voltage of the first voltage line VL1 is applied. The repair hole REH may be disposed so as not to overlap the first bank pattern BP1 and the second bank pattern BP2, but is not limited thereto. At least a portion of the repair hole REH may overlap the first bank pattern BP1 or the second bank pattern BP2. In another embodiment, the repair hole REH may overlap the first electrode RME1 and the first connection electrode CNE1, or may overlap the first bank pattern BP1 or the second bank pattern BP2. The arrangement of the repair hole REH is not particularly limited if it overlaps the first connection electrode CNE1 for repair.

A method of repairing defects caused by a short of the light emitting element ED in the display device 10 provided with the repair hole REH is as follows.

Referring to FIGS. 8 to 10, in case that a non-light emitting defect caused by a short of a light emitting element ED occurs, an overcurrent may be applied to the first connection electrode CNE1 exposed by the repair hole REH of the fourth insulating layer PAS4. In detail, the current may be applied after a metal tip or a conductive brush is brought into contact with the first connection electrode CNE1. The overcurrent may be not particularly limited if it is greater than a current applied in case that the light emitting element ED is normally driven. The method of applying the overcurrent through the repair hole REH may prevent a surface of the first connection electrode CNE1 from being damaged by the metal tip or the conductive brush, and may apply the overcurrent to only a desired path to enable a stable repair. When the overcurrent is applied to the light emitting element ED having a short defect, no current may flow to the light emitting element ED due to the overcurrent.

As shown in FIG. 10, in case that the overcurrent is applied to the shorted light emitting element ED, the first power voltage applied through the first connection electrode CNE1 may not flow to the light emitting element ED to which the overcurrent is applied, but may be applied to normal light emitting elements ED. Therefore, the light emitting elements ED of the subpixels SPXn that does not emit light due to the shorted light emitting element ED may be allowed to normally emit light, thereby repairing the defect. Therefore, problems related to the dark spots, luminance deterioration and non-uniform image quality of the display device 10 may be solved.

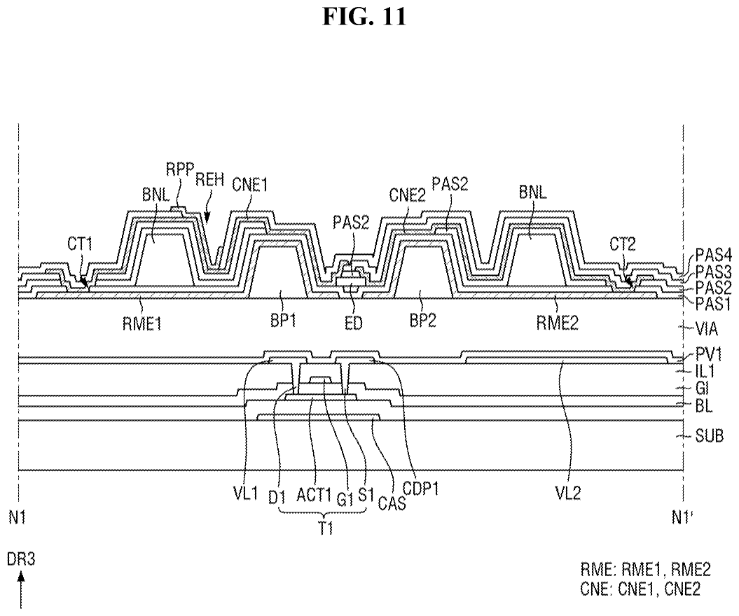

FIG. 11 is a schematic cross-sectional view schematically illustrating a subpixel of a display device according to another embodiment of the disclosure.

Referring to FIG. 11, the embodiment is different from the embodiment of FIGS. 4 to 10 at least in that the display device further includes a conductive pad RPP for covering the repair hole REH. Hereinafter, the same elements as those of the embodiment of FIGS. 4 to 10 will be omitted and the following description will be based on a difference from the embodiment of FIGS. 4 to 10.

The conductive pad RPP may be disposed on the fourth insulating layer PAS4. The conductive pad RPP may be disposed over the light emission area EMA and the non-light emission area of each subpixel SPXn. For example, a portion of the conductive pad RPP may overlap the bank layer BNL and another portion thereof may overlap the bank layer BNL, but the conductive pad RPP is not limited thereto. The conductive pad RPP may be disposed in the light emission area EMA, and the conductive pad RPP may not overlap the bank layer BNL. In another embodiment, the conductive pad RPP may be disposed in the non-light emission area, and the repair hole REH may overlap the bank layer BNL. The conductive pad RPP may overlap the repair hole REH, and may completely cover the repair hole REH. The arrangement of the conductive pad RPP may follow that of the repair hole REH.

The conductive pad RPP may overlap the first electrode RME1 and the first connection electrode CNE1 in the third direction DR3. The conductive pad RPP may contact (e.g., directly contact) the first connection electrode CNE1 to which the first power voltage of the first voltage line VL1 is applied. The conductive pad RPP may be disposed so as not to be overlapped with the first bank pattern BP1 and the second bank pattern BP2, but is not limited thereto. At least a portion of the conductive pad RPP may overlap the first bank pattern BP1 or the second bank pattern BP2.

The conductive pad RPP may include a conductive material. For example, the conductive pad RPP may include a metal such as silver (Ag), copper (Cu), and aluminum (Al) or a combination thereof, or an alloy containing aluminum (Al), nickel (Ni), lanthanum (La), etc., or may have a stacked structure in which a metal layer such as titanium (Ti), molybdenum (Mo) and niobium (Nb) and the alloy are stacked each other. In some embodiments, the conductive pad RRP may be a double layer or multiple layers in which an alloy containing aluminum (Al) and at least one metal layer of titanium (Ti), molybdenum (Mo) and niobium (Nb), or a combination thereof are stacked each other.

Without limitation to the above example, the conductive pad RPP may include a transparent conductive material. For example, the conductive pad RPP may include a material such as ITO, IZO, and ITZO, or a combination thereof. In some embodiments, the conductive pad RPP may have a structure in which one or more layers of a transparent conductive material and a metal layer are stacked each other, or may be formed as a single layer including the transparent conductive material and the metal layer. For example, the conductive pad RPP may have a stacked structure such as ITO/Ag/ITO/, ITO/Ag/IZO or ITO/Ag/ITZO/IZO.

In the embodiment, the conductive pad RPP protruded toward an upper portion of the fourth insulating layer PAS4 may be provided to facilitate contact with the metal tip or the conductive brush during a repair process. Therefore, the repair process may be facilitated.

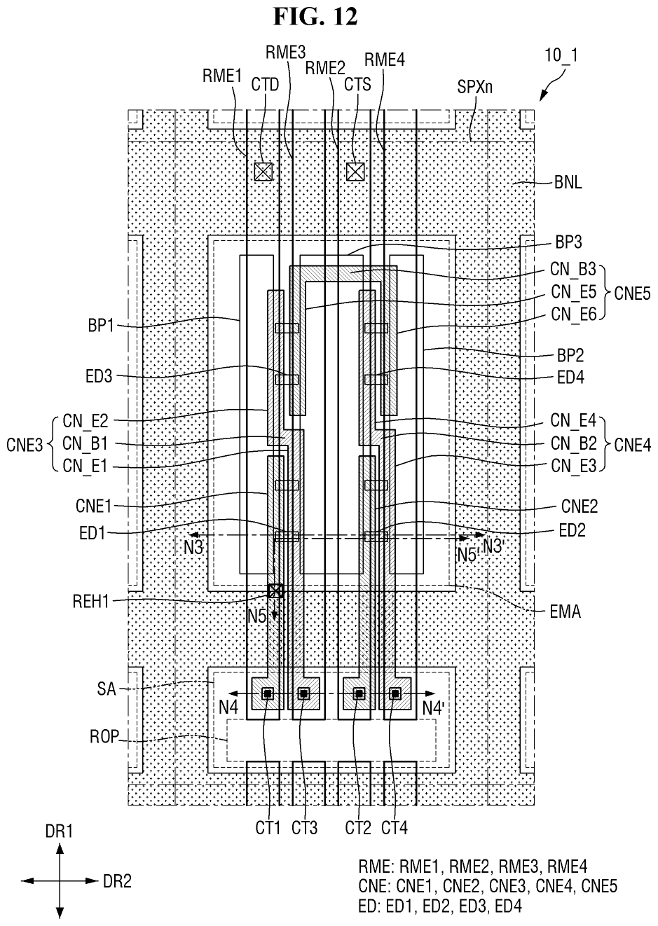

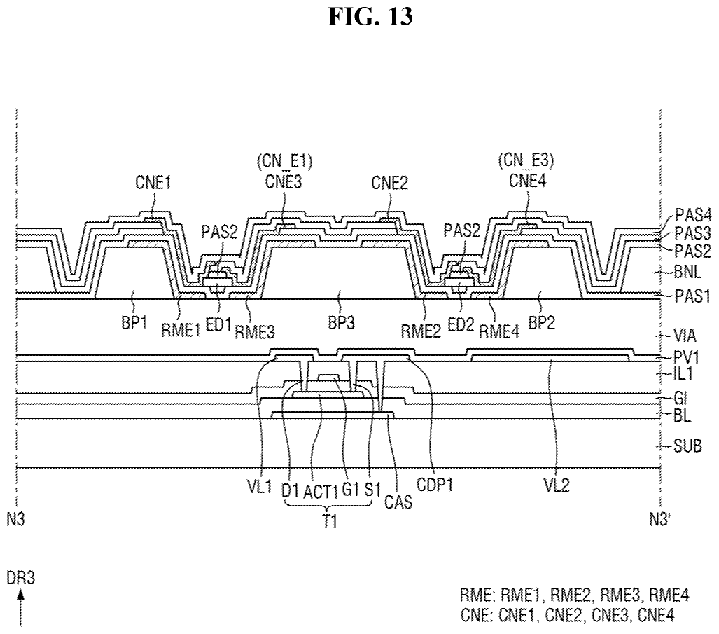

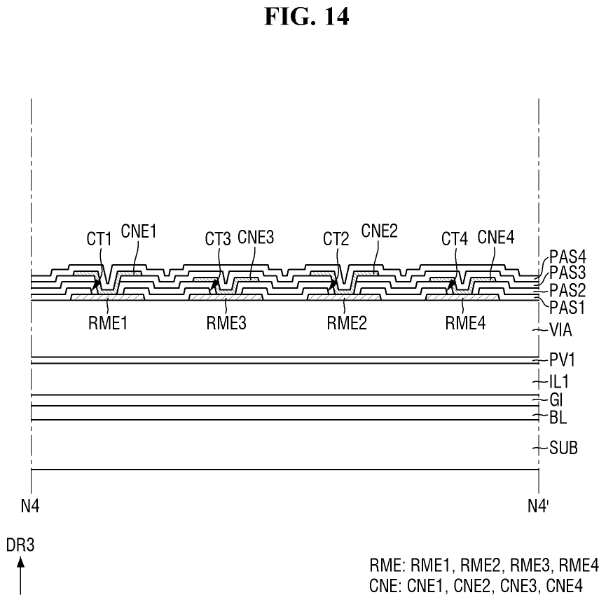

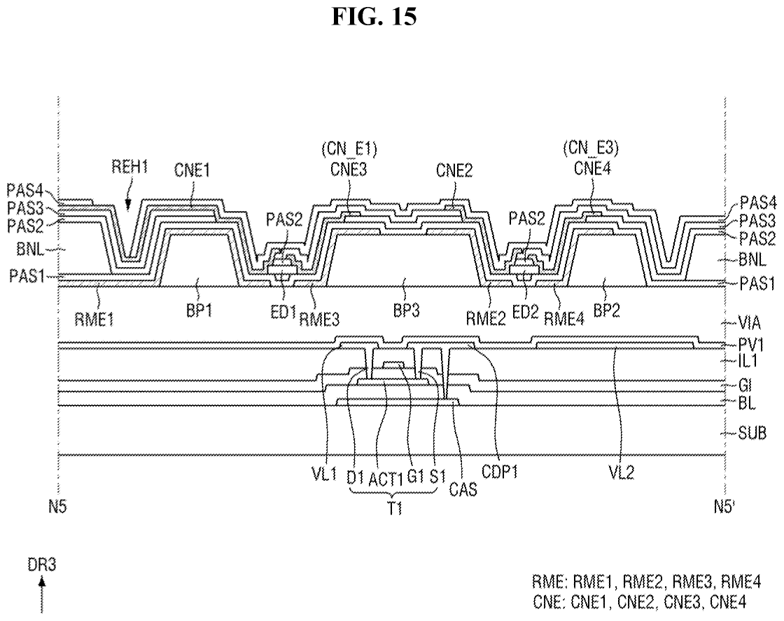

FIG. 12 is a schematic plan view illustrating a subpixel of a display device according to another embodiment of the disclosure. FIG. 13 is a schematic cross-sectional view taken along line N3-N3′ of FIG. 12. FIG. 14 is a schematic cross-sectional view taken along the line N4-N4′ of FIG. 12. FIG. 15 is a schematic cross-sectional view taken along the line N5-N5′ of FIG. 12. FIG. 13 shows a schematic cross-section crossing both ends of first and second light emitting elements ED1 and ED2 of FIG. 12, and FIG. 14 shows a schematic cross-section crossing contact portions CT1, CT2, CT3 and CT4 of FIG. 12.

Referring to FIGS. 12 to 15, a display device 10_1 according to an embodiment may include a larger number of electrodes RME and a larger number of connection electrodes CNE, and the number of light emitting elements ED disposed in each subpixel SPXn may be increased. The embodiment is different from the embodiment of FIGS. 4 to 11 at least in that the arrangement of the connection electrode CNE and the electrode RME of each subpixel SPXn and bank patterns BP1, BP2 and BP3 are different from those of FIGS. 4 to 11. Hereinafter, the repeated description will be omitted, and the following description will be based on a difference from the embodiment of FIGS. 4 to 11.

The bank pattern may further include a third bank pattern BP3 disposed between the first bank pattern BP1 and the second bank pattern BP2. The first bank pattern BP1 may be disposed on the left side based on the center of the light emission area EMA, the second bank pattern BP2 may be disposed on the right side based on the center of the light emission area EMA, and the third bank pattern BP3 may be disposed at the center of the light emission area EMA. A width of the third bank pattern BP3, which is measured in the second direction DR2, may be larger than the first bank pattern BP1 and the second bank pattern BP2. An interval among the bank patterns BP1, BP2 and BP3, which are spaced apart from one another in the second direction, may be greater than that between the respective electrodes RME. Therefore, at least a portion of each of the electrodes RME may be disposed so as not to overlap the bank patterns BP1, BP2 and BP3.

The electrodes RME disposed in each of the subpixels SPXn may further include a third electrode RME3 and a fourth electrode RME4 (in addition to the first electrode RME1 and the second electrode RME2).

The third electrode RME3 may be disposed between the first electrode RME1 and the second electrode RME2, and the fourth electrode RME4 may be spaced apart from the third electrode RME3 in the second direction DR2 with the second electrode RME2 interposed therebetween. The electrodes RME may be disposed such that the first electrode RME1, the third electrode RME3, the second electrode RME2 and the fourth electrode RME4 may be sequentially disposed from the left side to the right side of the subpixels SPXn.

Each of the electrodes RME may be disposed to be extended from the light emission area EMA to the sub-area SA while crossing the bank layer BNL. Among the electrodes RME, the first electrode RME1 and the second electrode RME2 may be electrically connected to the third conductive layer therebelow through the electrode contact holes CTD and CTS. However, the third electrode RME3 and the fourth electrode RME4 may not be connected (e.g., directly connected) to the third conductive layer therebelow, and may be electrically connected to the first electrode RME1 and the second electrode RME2 through the light emitting elements ED and the connection electrodes CNE. The first electrode RME1 and the second electrode RME2 may be first type electrodes connected (e.g., directly connected) to the third conductive layer through the electrode contact holes CTD and CTS, and the third electrode RME3 and the fourth electrode RME4 may be second type electrodes that are not connected (e.g., directly connected) to the third conductive layer. The second type electrodes may provide an electrical connection path of the light emitting elements ED together with the connection electrode CNE.

The light emitting elements ED may be disposed among the bank patterns BP1, BP2 and BP3 or on the different electrodes RME. A portion of the light emitting elements ED may be disposed between the first bank pattern BP1 and the third bank pattern BP3, and another portion thereof may be disposed between the third bank pattern BP3 and the second bank pattern BP2. According to an embodiment, the light emitting element ED may include the first light emitting element ED1 and the third light emitting element ED3, which are disposed between the first bank pattern BP1 and the third bank pattern BP3, and the second light emitting element ED2 and the fourth light emitting element ED4, which are disposed between the third bank pattern BP3 and the second bank pattern BP2. The first light emitting element ED1 and the third light emitting element ED3 may be disposed on the first electrode RME1 and the third electrode RME3, respectively, and the second light emitting element ED2 and the fourth light emitting element ED4 may be disposed on the second electrode RME2 and the fourth electrode RME4, respectively. The first light emitting element ED1 and the second light emitting element ED may be disposed to be adjacent to a lower side or the sub-area SA in the light emission area EMA of the corresponding subpixel SPXn, and the third light emitting element ED3 and the fourth light emitting element ED4 may be disposed to be adjacent to an upper side in the light emission area EMA of the corresponding subpixel SPXn. However, the respective light emitting elements ED may not be distinguished depending on their positions in the light emission area EMA but be distinguished depending on a connection relation with the connection electrode CNE that will be described below. The respective light emitting elements ED may have their respective connection electrodes CNE, with which both ends are in contact, depending on the arrangement structure of the connection electrodes CNE, and may be mutually distinguished depending on the types of the connection electrodes CNE that are in contact therewith.

The arrangement of the first insulating layer PAS1 may be the same as that described with reference to the embodiment of FIGS. 4 to 11. The first insulating layer PAS1 may be disposed entirely in the subpixels SPXn, and may include contact portions CT1, CT2, CT3 and CT4.

As a larger number of electrodes RME are disposed in each subpixel SPXn, the number of the contact portions CT1, CT2, CT3 and CT4 may be increased. In an embodiment, the sub-area SA may further include a third contact portion CT3 disposed on a portion of the third electrode RME3 and a fourth contact portion CT4 disposed on a portion of the fourth electrode RME4 (in addition to the first contact portion CT1 disposed on a portion of the first electrode RME1 and the second contact portion CT2 disposed on a portion of the second electrode RME2). Each of the contact portions CT1, CT2, CT3 and CT4 may expose a portion of an upper surface of each of the electrodes RME1, RME2, RME3 and RME4 by passing through the first insulating layer PAS1.

The connection electrodes CNE may further include a third connection electrode CNE3, a fourth connection electrode CNE4 and a fifth connection electrode CNE5, which are disposed over the electrodes RME (in addition to the first connection electrode CNE1 disposed on the first electrode RME1 and the second connection electrode CNE2 disposed on the second electrode RME2).

Unlike the embodiment of FIGS. 4 to 11, each of the first connection electrode CNE1 and the second connection electrode CNE2 may have a relatively short length extended in the first direction DR1. The first connection electrode CNE1 and the second connection electrode CNE2 may be disposed at a lower side based on the center of the light emission area EMA. The first connection electrode CNE1 and the second connection electrode CNE2 may be disposed over the light emission area EMA and the sub-area SA of the corresponding subpixel SPXn, and may electrically contact the first electrode RME1 and the second electrode RME2 through the first contact portion CT1 and the second contact portion CT2, which are formed in the sub-area SA, respectively.

The third connection electrode CNE3 may include a first extension portion CN_E1 disposed on the third electrode RME3, a second extension portion CN_E2 disposed on the first electrode RME1, and a first connection portion CN_B1 connecting the first extension portion CN_E1 with the second extension portion CN_E2. The first extension portion CN_E1 may be spaced apart from the first connection electrode CNE1 in the second direction DR2 to face the first connection electrode CNE1, and the second extension portion CN_E2 may be spaced apart from the first connection electrode CNE1 in the first direction DR1. The first extension portion CN_E1 may be disposed on the lower side of the light emission area EMA of the corresponding subpixel SPXn, and the second extension portion CN_E2 may be disposed on the upper side of the light emission area EMA. The first extension portion CN_E1 may be disposed over the light emission area EMA and the sub-area SA and thus electrically connected to the third electrode RME3 through the third contact portion CT3 formed in the sub-area SA. The first connection portion CN_B1 may be disposed over the first electrode RME1 and the third electrode RME3 at the center of the light emission area EMA. The third connection electrode CNE3 may have a shape extended generally in the first direction DR1, but may have a shape bent in the second direction DR2 and extended in the first direction DR1.

The fourth connection electrode CNE4 may include a third extension portion CN_E3 disposed on the fourth electrode RME4, a fourth extension portion CN_E4 disposed on the second electrode RME2, and a second connection portion CN_B2 connecting the third extension portion CN_E3 with the fourth extension portion CN_E4. The third extension portion CN_E3 may be spaced apart from the second connection electrode CNE2 in the second direction DR2 to face the second connection electrode CNE2, and the fourth extension portion CN_E4 may be spaced apart from the second connection electrode CNE2 in the first direction DR1. The third extension portion CN_E3 may be disposed on the lower side of the light emission area EMA of the corresponding subpixel SPXn, and the fourth extension portion CN_E4 may be disposed on the upper side of the light emission area EMA. The third extension portion CN_E3 may be disposed in the light emission area EMA and the sub-area SA and thus electrically connected to the fourth electrode RME4 through the fourth contact portion CT4. The second connection portion CN_B2 may be disposed over the second electrode RME2 and the fourth electrode RME4 by adjoining the center of the light emission area EMA. The fourth connection electrode CNE4 may have a shape extended generally in the first direction DR1, but may have a shape bent in the second direction DR2 and extended in the first direction DR1.

The fifth connection electrode CNE5 may include a fifth extension portion CN_E5 disposed on the third electrode RME3, a sixth extension portion CN_E6 disposed on the fourth electrode RME4, and a third connection portion CN_B3 connecting the fifth extension portion CN_E5 with the sixth extension portion CN_E6. The fifth extension portion CN_E5 may be spaced apart from the second extension portion CN_E2 of the third connection electrode CNE3 in the second direction DR2 to face the second extension portion CN_E2, and the sixth extension portion CN_E6 may be spaced apart from the fourth extension portion CN_E4 of the fourth connection electrode CNE4 in the second direction DR2 to face the fourth extension portion CN_E4. The fifth extension portion CN_E5 and the sixth extension portion CN_E6 may be disposed on the upper side of the light emission area EMA, and the third connection portion CN_B3 may be disposed over the third electrode RME3, the second electrode RME2 and the fourth electrode RME4. The fifth connection electrode CNE5 may be disposed in a shape surrounding the fourth extension portion CN_E4 of the fourth connection electrode CNE4 on a plan view.

The first connection electrode CNE1 and the second connection electrode CNE2 may be first type connection electrodes that electrically contact the first electrode RME1 and the second electrode RME2, which are connected (e.g., directly connected) to the third conductive layer, the third connection electrode CNE3 and the fourth connection electrode CNE4 may be second type connection electrodes that electrically contact the third electrode RME3 and the fourth electrode RME4, which are not connected (e.g., directly connected) to the third conductive layer, and the fifth connection electrode CNE5 may be a third type connection electrode that does not electrically contact the electrodes RME3.

As described above, the light emitting elements ED may be divided into different light emitting elements depending on the connection electrode CNE with which both ends of the light emitting elements ED are in contact, in response to the arrangement structure of the connection electrodes CNE.

A first end of the first light emitting element ED1 and the second light emitting element ED2 may electrically contact the first type connection electrode and a second end thereof may electrically contact the second type connection electrode. The first light emitting element ED1 may electrically contact the first connection electrode CNE1 and the third connection electrode CNE3, and the second light emitting element ED2 may electrically contact the second connection electrode CNE2 and the fourth connection electrode CNE4. A first end of the third light emitting element ED3 and the fourth light emitting element ED4 may electrically contact the second type connection electrode and a second end thereof may electrically contact the third type connection electrode. The third light emitting element ED3 may electrically contact the third connection electrode CNE3 and the fifth connection electrode CNE5, and the fourth light emitting element ED4 may electrically contact the fourth connection electrode CNE4 and the fifth connection electrode CNE5.

The light emitting elements ED may be electrically connected to one another in series through the connection electrodes CNE. The display device 10_1 according to the embodiment may include a larger number of light emitting elements ED for each subpixel SPXn and may constitute a series connection of the light emitting elements ED, whereby the amount of light emission per unit area may be more increased.

The fourth insulating layer PAS4 may include a repair hole REH that exposes the first connection electrode CNE1. The repair hole REH may be disposed in each of the subpixels SPXn. The repair hole REH may be disposed over the light emission area EMA and the non-light emission area of each of the subpixels SPXn. For example, a portion of the repair hole REH may overlap the bank layer BNL, and another portion thereof may not overlap the bank layer BNL, but the repair hole REH is not limited thereto. The repair hole REH may be disposed in the light emission area EMA, and in this case, the repair hole REH may not overlap the bank layer BNL. In another embodiment, the repair hole REH may be disposed in the non-light emission area, and in this case, the repair hole REH may overlap the bank layer BNL.

The repair hole REH may overlap the first electrode RME1 and the first connection electrode CNE1 in the third direction DR3. The repair hole REH may expose the first connection electrode CNE1 to which the first power voltage of the first voltage line VL1 is applied. The repair hole REH may be disposed so as not to overlap the first bank pattern BP1, the second bank pattern BP2 and the third bank pattern BP3, but is not limited thereto. At least a portion of the repair hole REH may overlap the first bank pattern BP1, the second bank pattern BP2 or the third bank pattern BP3.

In case that a non-light emitting defect caused by a short of the light emitting element ED occurs, the display device 10 provided with the repair hole REH may repair the non-light emitting defect by applying an overcurrent to the first connection electrode CNE1 exposed by the repair hole REH of the fourth insulating layer PAS4. The method of applying the overcurrent through the repair hole REH may prevent a surface of the first connection electrode CNE1 from being damaged by the metal tip or the conductive brush, and may apply the overcurrent to only a desired path to enable a stable repair.

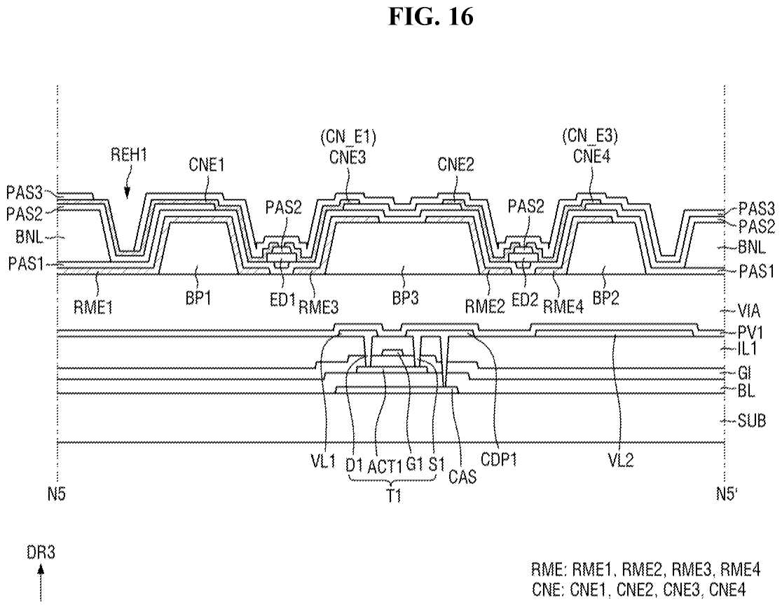

FIG. 16 is a schematic cross-sectional view illustrating a subpixel of a display device according to still another embodiment of the disclosure.

Referring to FIG. 16, the embodiment is different from the embodiment of FIG. 5 at least in that the third insulating layer PAS3 of FIG. 16 is omitted so that the first connection electrode CNE1 and the second connection electrode CNE2 are disposed on the first insulating layer PAS1, respectively. Hereinafter, the same elements as those of the embodiment of FIG. 15 will be omitted and a difference from the embodiment of FIG. 5 will be described.

Each of the connection electrodes CNE may be disposed on the first insulating layer PAS1. In detail, the first connection electrode CNE1 may be disposed on the first insulating layer PAS1, and thus may contact (e.g., directly contact) one end of the first light emitting element ED1. The second connection electrode CNE2 may also be disposed on the first insulating layer PAS1 and thus may contact (e.g., directly contact) one end of the second light emitting element ED2. Although not shown, the fifth connection electrode (‘CNE5’ in FIG. 12) may be disposed on the first insulating layer PAS1.

The third insulating layer PAS3 may be disposed entirely on each of the connection electrodes CNE and the second insulating layer PAS2. The arrangement of the third insulating layer PAS3 may be the same as that of the fourth insulating layer PAS4 of FIGS. 12 to 15.

In the embodiment, the repair hole REH that exposes the first connection electrode CNE1 may be formed in the third insulating layer PAS3 covering the first connection electrode CNE1, thereby repairing a non-light emitting defect caused by a short of the light emitting elements ED.

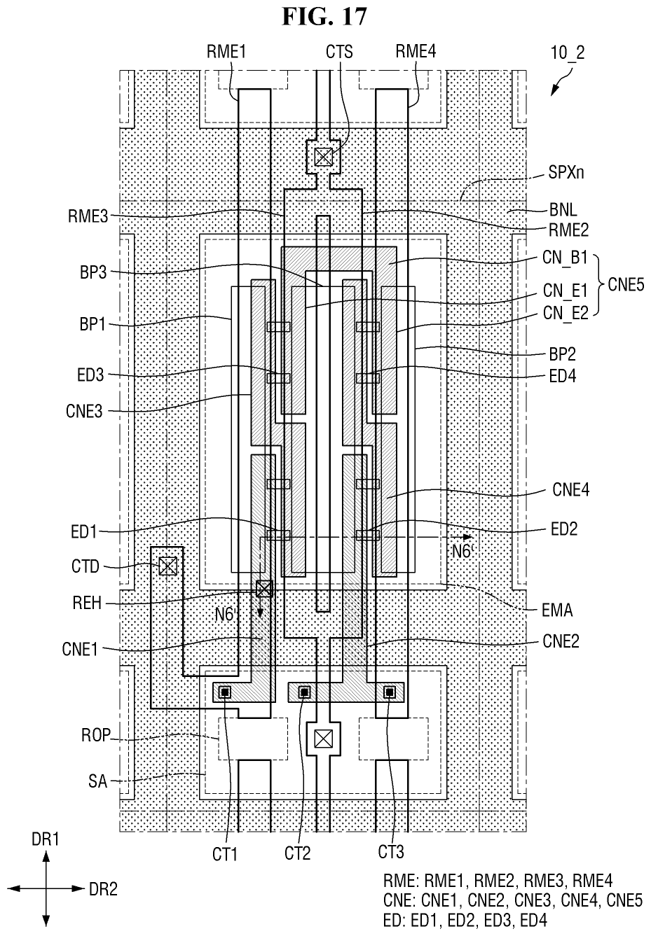

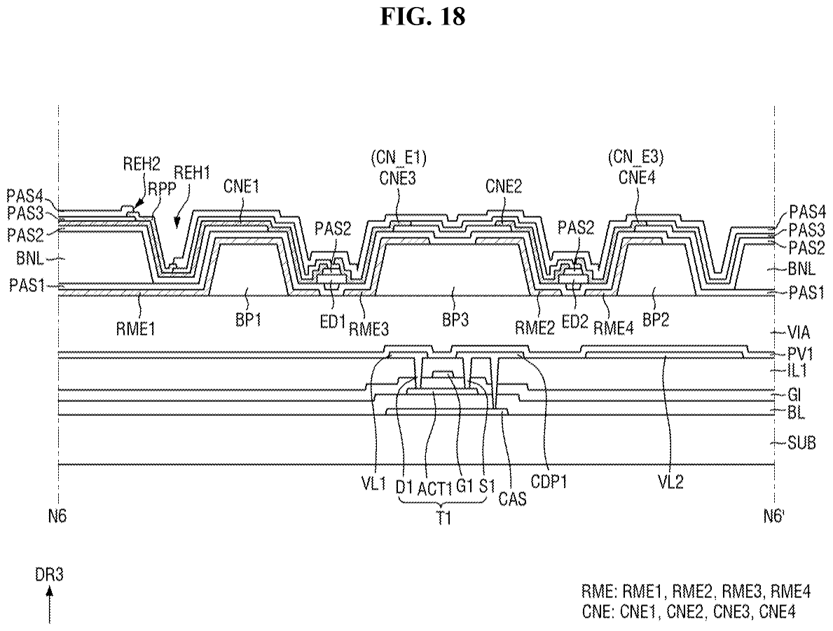

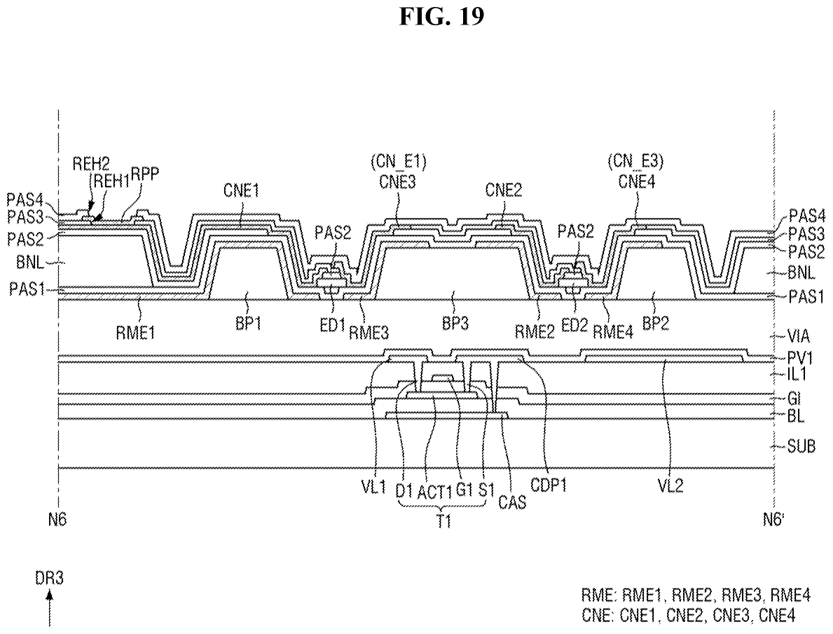

FIG. 17 is a schematic plan view illustrating a subpixel of a display device according to further still another embodiment of the disclosure. FIG. 18 is a schematic cross-sectional view illustrating on example taken along line N6-N6′ of FIG. 17. FIG. 19 is schematic a cross-sectional view illustrating another example taken along the line N6-N6′ of FIG. 17.

FIG. 17 shows a planar arrangement of electrodes RME; RME1, RME2, RME3 and RME4, bank patterns BP1, BP2 and BP3 and a bank layer BNL, light emitting elements ED and connection electrodes CNE; CNE1, CNE2, CNE3, CNE4 and CNE5, which are disposed in a subpixel SPXn of a display device 10_2.

Referring to FIG. 17, the display device 10_2 according to an embodiment is different from the embodiment of FIG. 12 at least in that some of the electrodes RME1, RME2, RME3 and RME4 have different structures. For example, some of the electrodes RME1, RME2, RME3 and RME4 may be electrically connected to each other, and another some thereof may further include a portion extended in the first direction DR1 and a portion bent from the portion, which is extended in the first direction DR1, in the second direction DR2. Hereinafter, the repeated description will be omitted, and the following description will be based on a difference from the embodiment of FIG. 12.

Referring to FIGS. 18 and 19 in relation to FIG. 17, the electrodes RME arranged in each subpixel SPXn may include a first electrode RME1, a second electrode RME2, a third electrode RME3 and a fourth electrode RME4.

The electrodes RME; RME1, RME2, RME3 and RME4 may be extended generally in the first direction DR1 and disposed to be spaced apart from each other. The first electrode RME1 may be disposed on a left side that is one side of the second direction DR2 in the light emission area EMA of each subpixel SPXn. The second electrode RME2 may be disposed to be spaced apart from the first electrode RME1 in the second direction DR2, the third electrode RME3 may be disposed between the first electrode RME1 and the second electrode RME2, and the fourth electrode RME4 may be disposed to be spaced apart from the third electrode RME3 in the second direction DR2 with the second electrode RME2 interposed therebetween. The respective electrodes RME may be spaced apart from each other in the second direction DR2 to face each other. The first electrode RME1 and the fourth electrode RME4 of the electrodes RME may be spaced apart from the electrodes RME of another subpixel SPXn adjacent thereto in the first direction DR1 in the partition portion ROP of the sub-area SA.

According to an embodiment of the disclosure, the first electrode RME1 may include a main portion extended in the first direction DR1 and a protrusion portion bent from the main portion in the second direction DR2 and bent in the first direction DR1. The main portion of the first electrode RME1 may be disposed to cross the light emission area EMA and the sub-area SA of each subpixel SPXn, and a portion thereof may be disposed on the first bank pattern BP1. The protrusion portion of the first electrode RME1 may be electrically connected to a portion disposed in the sub-area SA of the main portion, and may be disposed to overlap a portion of the bank layer BNL, which is extended in the first direction DR1. The protrusion portion of the first electrode RME1 may electrically contact the first conductive pattern through the first electrode contact hole CTD.

A portion of the second electrode RME2 and a portion the third electrode RME3 may be integrated with each other. For example, the second electrode RME2 and the third electrode RME3 may be integrally connected to (or integral with) each other in a portion where they are disposed in the sub-area SA, and a portion where they are positioned above the light emission area EMA to overlap the bank layer BNL. A portion of the second electrode RME2 and the third electrode RME3, which are integrated with each other and disposed below the bank layer BNL, may electrically contact the second voltage line through the second electrode contact hole CTS. The fourth electrode RME4 may have a shape extended in the first direction DR1, and may not be connected (e.g., directly connected) to the other electrode RME.

The first insulating layer PAS1 may be disposed in a similar structure to that of the above-described embodiment. The first insulating layer PAS1 may be disposed entirely on the display area DPA, and may cover the electrodes RME and the bank patterns BP1, BP2 and BP3.

According to an embodiment, the first insulating layer PAS1 may include contact portions CT1, CT2 and CT3. The contact portions CT1, CT2 and CT3 formed in the first insulating layer PAS1 may be disposed to overlap different electrodes RME and lines, respectively. For example, the contact portions CT1, CT2 and CT3 may be disposed in the sub-area SA, and may include a first contact portion CT1 disposed to overlap the first electrode RME1, a second contact portion CT2 disposed to overlap the second voltage line and a third contact portion CT3 disposed to overlap the fourth electrode RME4. The contact portions CT1, CT2 and CT3 may expose a portion of an upper surface of the electrodes RME1 and RME4 and the second voltage lines below the first insulating layer PAS1 by passing through the first insulating layer PAS1. The respective contact portions CT1, CT2 and CT3 may further pass through some of the other insulating layers disposed on the first insulating layer PAS1.

The light emitting elements ED may be disposed among the bank patterns BP1, BP2 and BP3 or on the different electrodes RME. A portion of the light emitting elements ED may be disposed between the first bank pattern BP1 and the third bank pattern BP3 and another portion thereof may be disposed between the third bank pattern BP3 and the second bank pattern BP2. According to an embodiment, the light emitting element ED may include a first light emitting element ED1 and a third light emitting element ED3, which are disposed between the first bank pattern BP1 and the third bank pattern BP3, and a second light emitting element ED2 and a fourth light emitting element ED4, which are disposed between the third bank pattern BP3 and the second bank pattern BP2. The description of the different light emitting elements ED1, ED2, ED3 and ED4 is the same as that described with reference to FIG. 12.

The second insulating layer PAS2 may be disposed in a similar structure to that of the above-described embodiment. The second insulating layer PAS2 may be disposed on the light emitting elements ED, the first insulating layer PAS1 and the bank layer BNL.

The connection electrodes CNE may include a first connection electrode CNE1 and a third connection electrode CNE3, which are disposed on the first electrode RME1, a second connection electrode CNE3 and a fourth connection electrode CNE4, which are disposed on the second electrode RME2, the third connection electrode CNE3 and a fifth connection electrode CNE5 disposed on the third electrode RME3, and a fourth connection electrode CNE4 and the fifth connection electrode CNE5, which are disposed on the fourth electrode RME4.

The first connection electrode CNE1 and the second connection electrode CNE2 may be disposed over the light emission area EMA and the sub-area SA of the corresponding subpixel SPXn, and may contact (e.g., directly contact) the first electrode RME1 and the fourth electrode RME4 through the first contact portion CT1 and the third contact portion CT3, which are formed in the sub-area SA, respectively. Also, the second connection electrode CNE2 may be electrically connected to the second voltage line through the second contact portion CT2 formed in the sub-area SA. The first connection electrode CNE1 may contact (e.g., directly contact) the first electrode RME1 in the sub-area SA through the first contact portion CT1 that passes through the first insulating layer PAS1 and the second insulating layer PAS2. The first connection electrode CNE1 may electrically contact the protrusion portion protruded from the main portion of the first electrode RME1. The second connection electrode CNE2 may electrically contact the fourth electrode RME4 in the sub-area SA through the third contact portion CT3 that passes through the first insulating layer PAS1 and the second insulating layer PAS2. The second connection electrode CNE2 may be electrically connected to the fourth electrode RME4 and the second voltage line. As described above, the second electrode RME2 and the third electrode RME3 may be integrated with each other and electrically connected to the second voltage line VL2 through the second electrode contact hole CTS, and the fourth electrode RME4 may be electrically connected to the second electrode RME2, the third electrode RME3 and the second voltage line VL2 through the second connection electrode CNE2.

The other third, fourth and fifth connection electrodes CNE3, CNE4 and CNE5 are the same as those described with reference to FIG. 12.

The first connection electrode CNE1, the second connection electrode CNE2 and the fifth connection electrode CNE5 may be the connection electrodes of the first connection electrode layer disposed on the first insulating layer PAS1 and the second insulating layer PAS2, and the third connection electrode CNE3 and the fourth connection electrode CNE4 may be the connection electrodes of the second connection electrode layer disposed on the third insulating layer PAS3. The third insulating layer PAS3 may be disposed between the first connection electrode layer and the second connection electrode layer.

The third insulating layer PAS3 may be disposed in a similar structure to that of the above-described embodiment. The third insulating layer PAS3 may be disposed on the second insulating layer PAS2 except the area in which the second connection electrode layer is disposed.

According to an embodiment, the third insulating layer PAS3 may include a first repair hole REH1. The third insulating layer PAS3 may include a first repair hole REH1 that exposes the first connection electrode CNE1. The first repair hole REH1 may be disposed in each of the subpixels SPXn. The first repair hole REH1 may be disposed over the light emission area EMA and the non-light emission area of each subpixel SPXn. For example, a portion of the first repair hole REH1 may overlap the bank layer BNL and another portion thereof may not overlap the bank layer BNL. In another embodiment, as shown in FIG. 19, the first repair hole REH1 may be disposed in the non-light emission area, and the first repair hole REH1 may overlap the bank layer BNL.

The first repair hole REH1 may overlap the first electrode RME1 and the first connection electrode CNE1 in the third direction DR3. The first repair hole REH1 may expose the first connection electrode CNE1 to which the first power voltage is applied. The first repair hole REH1 may be disposed so as not to overlap the first bank pattern BP1, but is not limited thereto. The first repair hole REH1 may overlap the first bank pattern BP1.

The conductive pad RPP may be disposed on the first repair hole REH1 and the third insulating layer PAS3. The conductive pad RPP may be disposed over the light emission area EMA and the non-light emission area of each subpixel SPXn. For example, a portion of the conductive pad RPP may overlap the bank layer BNL and another portion thereof may not overlap the bank layer BNL. In another embodiment, as shown in FIG. 19, the conductive pad RPP may be disposed in the non-light emission area, and the conductive pad RPP may overlap the bank layer BNL and the first repair hole REH1.

The conductive pad RPP may overlap the first electrode RME1 and the first connection electrode CNE1 in the third direction DR3. The conductive pad RPP may contact (e.g., directly contact) the first connection electrode CNE1 to which the first power voltage is applied. The conductive pad RPP may be disposed so as not to overlap the first bank pattern BP1. However, at least a portion of the conductive pad RPP may overlap the first bank pattern BP1.

The conductive pad RPP may include a conductive material. In an embodiment, the conductive pad RPP, the third connection electrode CNE3, and the fourth connection electrode CNE4 may include a same material. The conductive pad RPP may be formed simultaneously with the third connection electrode CNE3 and the fourth connection electrode CNE4 to simplify the process.

The fourth insulating layer PAS4 may be disposed on the third insulating layer PAS3, the third connection electrode CNE3 and the fourth connection electrode CNE4. The fourth insulating layer PAS4 may be disposed in a similar structure to that of the above-described embodiment. The fourth insulating layer PAS4 may be disposed entirely on the display area except the area in which the conductive pad RPP is disposed.

According to an embodiment, the fourth insulating layer PAS4 may include a second repair hole REH2. The fourth insulating layer PAS4 may include a second repair hole REH2 that exposes the conductive pad RPP. The second repair hole REH2 may be disposed in each of the subpixels SPXn. The second repair hole REH2 may be disposed over the light emission area EMA and the non-light emission area of each of the subpixels SPXn. For example, a portion of the second repair hole REH2 may overlap the bank layer BNL and another portion thereof may not overlap the bank layer BNL. In another embodiment, as shown in FIG. 19, the second repair hole REH2 may not overlap the light emission area EMA, and may be disposed in the non-light emission area. The second repair hole REH2 may overlap the bank layer BNL.

The second repair hole REH2 may overlap the first electrode RME1, the first connection electrode CNE1, the first repair hole REH1 and the conductive pad RPP in the third direction DR3. The second repair hole REH2 may expose the conductive pad RPP connected to the first connection electrode CNE1.

In the embodiment, the conductive pad RPP exposed upwardly through the second repair hole REH2 of the fourth insulating layer PAS4 may be provided to facilitate contact with the metal tip or the conductive brush during the repair process. Therefore, the repair process may be facilitated.

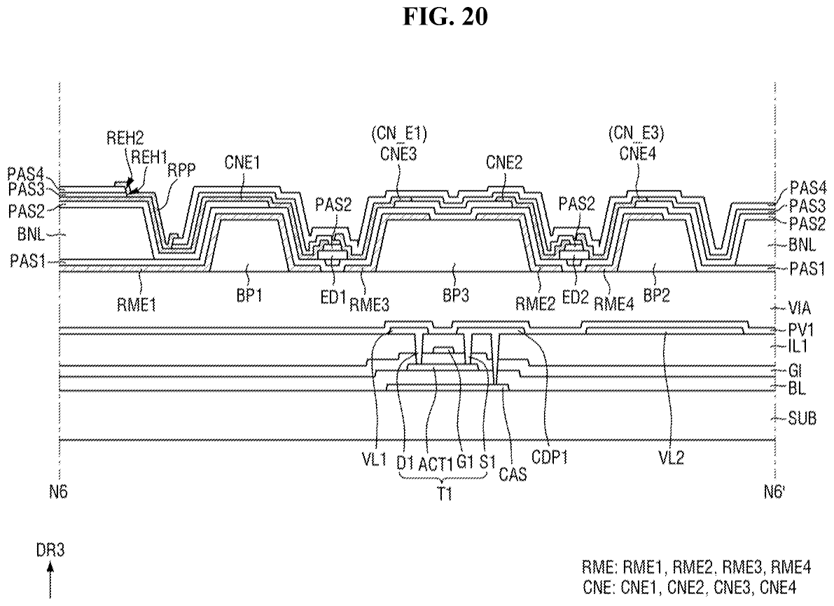

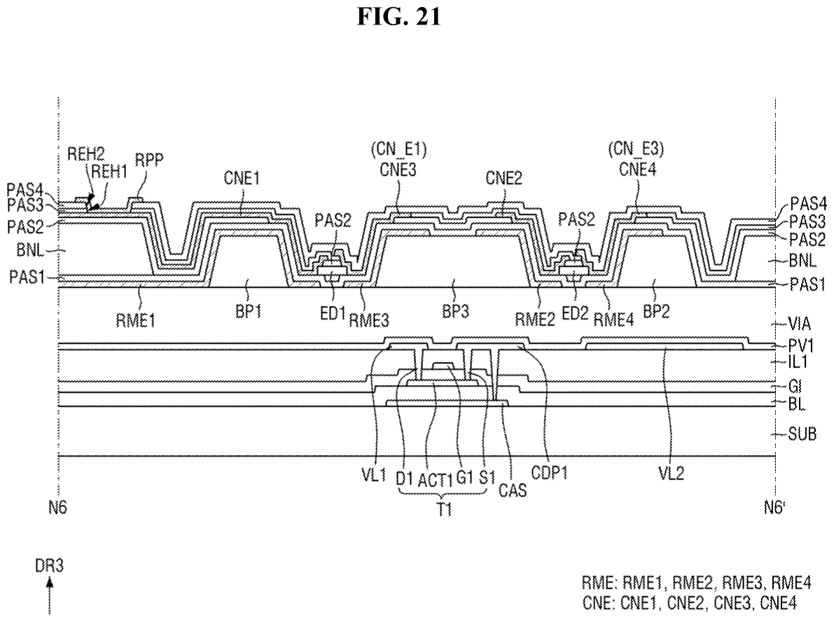

FIG. 20 is a schematic cross-sectional view illustrating an example of a subpixel of a display device according to further still another embodiment of the disclosure. FIG. 21 is a schematic cross-sectional view illustrating another example of a subpixel of a display device according to further still another embodiment of the disclosure.

Referring to FIGS. 20 and 21, the embodiment is different from the embodiment of FIGS. 17 to 19 at least in that the conductive pad RPP covers the first repair hole REH1 and the second repair hole REH2. Hereinafter, the repeated description with the embodiment of FIGS. 17 to 19 will be omitted and a difference from the embodiment of FIGS. 17 to 19 will be described.

The conductive pad RPP may be disposed on the fourth insulating layer PAS4. The conductive pad RPP may be disposed over the light emission area EMA and the non-light emission area of each subpixel SPXn. For example, a portion of the conductive pad RPP may overlap the bank layer BNL and another portion thereof may not overlap the bank layer BNL, but the conductive pad RPP is not limited thereto. As shown in FIG. 21, the conductive pad RPP may not overlap the light emission area EMA, and may be disposed in the non-light emission area. The first repair hole REH1 and the second repair hole REH2 may overlap the bank layer BNL. The conductive pad RPP may overlap the first repair hole REH1 and the second repair hole REH2.

The conductive pad RPP may overlap the first electrode RME1 and the first connection electrode CNE1 in the third direction DR3. The conductive pad RPP may contact (e.g., directly contact) the first connection electrode CNE1 to which the first power voltage is applied. The conductive pad RPP may contact (e.g., directly contact) the first connection electrode CNE1 exposed by the first repair hole REH1 and the second repair hole REH2.

In the embodiment, the conductive pad RPP protruded toward the upper portion of the fourth insulating layer PAS4 may be provided to facilitate contact with the metal tip or the conductive brush during the repair process. Therefore, the repair process may be facilitated.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode and a second electrode which are disposed on a substrate and spaced apart from each other;
a first insulating layer disposed on the first electrode and the second electrode;
a light emitting element disposed on the first insulating layer and having ends aligned on the first electrode and the second electrode;
a first connection electrode disposed on the first electrode and electrically contacting an end of the light emitting element;
a second connection electrode disposed on the second electrode and electrically contacting another end of the light emitting element; and
a second insulating layer disposed on the first connection electrode and including a repair hole that exposes a portion of the first connection electrode.

2. The display device of claim 1, wherein at least a portion of the repair hole overlaps the first connection electrode in a plan view.

3. The display device of claim 1, further comprising:
a bank layer disposed on the first insulating layer and partitioning a light emission area, wherein
the light emitting element is disposed in the light emission area, and
a sub-area is spaced apart from the light emission area in a plan view.

4. The display device of claim 3, wherein the repair hole overlaps the light emission area and the bank layer in a plan view.

5. The display device of claim 3, wherein the repair hole does not overlap the light emission area and overlaps the bank layer in a plan view.

6. The display device of claim 1, further comprising:
a conductive pad disposed on the second insulating layer and electrically contacting the first connection electrode through the repair hole.

7. The display device of claim 6, wherein the conductive pad overlaps the repair hole in a plan view, and completely covers the repair hole.

8. The display device of claim 1, further comprising:
at least one transistor disposed on the substrate,
wherein a power voltage is applied to the first connection electrode through the at least one transistor.

9. The display device of claim 1, further comprising:
a third insulating layer covering a portion of the light emitting element; and
a fourth insulating layer covering the third insulating layer and the second connection electrode,
wherein the second insulating layer covers the third insulating layer and the fourth insulating layer.

10. The display device of claim 9, wherein
the first connection electrode is disposed between the third insulating layer and the fourth insulating layer, and
the second connection electrode is disposed between the second insulating layer and the third insulating layer.

11. A display device comprising:
a first electrode and a second electrode which are disposed on a substrate, extended in a first direction and spaced apart from each other in a second direction;
a third electrode spaced apart from the first electrode and the second electrode in the second direction between the first electrode and the second electrode;
a fourth electrode spaced apart from the first electrode in the first direction;
light emitting elements including:
a first light emitting element having ends disposed on the first electrode and the third electrode; and
a second light emitting element having ends disposed on the second electrode and the fourth electrode;
a first connection electrode disposed on the first electrode and electrically contacting the first light emitting element;
a second connection electrode disposed on the second electrode and electrically contacting the second light emitting element;
a third connection electrode disposed on the third electrode and electrically contacting the first light emitting element;
a fourth connection electrode disposed on the fourth electrode and electrically contacting the second light emitting element; and
a first insulating layer disposed on the first connection electrode and including a first repair hole that exposes a portion of the first connection electrode.

12. The display device of claim 11, wherein at least a portion of the first repair hole overlaps the first connection electrode in a plan view.

13. The display device of claim 11, further comprising:
a conductive pad disposed on the first insulating layer and electrically contacting the first connection electrode through the first repair hole.

14. The display device of claim 13, further comprising:
a second insulating layer disposed on the first insulating layer and including a second repair hole that exposes the conductive pad,
wherein the first repair hole and the second repair hole overlap each other in a plan view.

15. The display device of claim 13, wherein
the first connection electrode and the second connection electrode, and the third connection electrode and the fourth connection electrode are disposed on different layers, and
the conductive pad, the third connection electrode, and the fourth connection electrode include a same material.

16. The display device of claim 13, further comprising:
a second insulating layer disposed between the first insulating layer and the conductive pad and including a second repair hole that exposes the first repair hole,
wherein the conductive pad electrically contacts the first connection electrode through the first repair hole and the second repair hole.

17. The display device of claim 11, wherein
the first connection electrode, the second connection electrode, the third connection electrode, and the fourth connection electrode are disposed on a same layer, and
the first insulating layer covers the first connection electrode, the second connection electrode, the third connection electrode, and the fourth connection electrode.

18. The display device of claim 11, further comprising:
at least one transistor disposed on the substrate,
wherein a power voltage is applied to the first connection electrode through the at least one transistor.

19. The display device of claim 11, further comprising:
a bank layer disposed on the substrate and partitioning a light emission area, wherein
the light emitting element is disposed in the light emission area,
a sub-area is spaced apart from the light emission area, and
the first repair hole overlaps the bank layer in a plan view.

20. The display device of claim 19, wherein the first repair hole does not overlap the light emission area in a plan view.
